(19) United States
(12) Patent Application Publication
(10) Pub. No.: US 2026/0206470 A1
(43) Pub. Date: Jul. 16, 2026

(54) DISPLAY DEVICE AND ELECTRONIC DEVICE INCLUDING THE SAME

(71) Applicant: Samsung Display Co., Ltd., Yongin-si (KR)

(72) Inventors: Ji Won LEE, Yongin-si (KR); Gun Shik KIM, Yongin-si (KR); Ju Hwa HA, Yongin-si (KR)

(21) Appl. No.: 19/292,448

(22) Filed: Aug. 6, 2025

(30) Foreign Application Priority Data
Jan. 14, 2025 (KR) 10-2025-0005396

(51) Int. Cl. H10K 59/80; H10H 29/855

(52) U.S. Cl. CPC H10K 59/879; H10H 29/855; H10K 59/8793

(57) ABSTRACT

Provided are a display device and electronic device including the same, the display device including a display panel, a first polarizing film above the display panel, a first phase retardation on the first polarizing film, and a triplet lens above the first polarizing film, and including a semi-transmissive reflective film, a first lens above the semi-transmissive reflective film, a second lens above the first lens, a second phase retardation film above the second lens, a second polarizing film above the second phase retardation film, a third lens above the second polarizing film, and a first adhesive layer between the first lens and the second lens, and having a refractive index that is greater than a refractive index of the first lens and a refractive index of the second lens.

### CROSS-REFERENCE TO RELATED APPLICATION

The present application claims priority to, and the benefit of, Korean Patent Application No. 10-2025-0005396, filed on Jan. 14, 2025, in the Korean Intellectual Property Office, the entire disclosure of which is incorporated herein by reference.

### BACKGROUND

### 1. Field

The present disclosure relates to a display device and an electronic device including the same.

### 2. Description of the Related Art

A head-mounted display (HMD) is an image display device that is worn on a user's head in the form of glasses or helmets to form a focus at a close distance in front of the user's eyes. The head-mounted display may implement virtual reality (VR) or augmented reality (AR).

The head-mounted display magnifies an image displayed on a small display device by using a plurality of lenses, and displays the magnified image. Therefore, the display device applied to the head-mounted display needs to provide high-resolution images, for example, images with a resolution of about 3000 PPI (Pixels Per Inch) or higher. To this end, an organic light-emitting diode on silicon (OLEDoS), which is a high-resolution small organic light-emitting display device, is used as the display device applied to the head-mounted display. The OLEDoS is an image display device in which an organic light-emitting diode (OLED) is located on a semiconductor wafer substrate including complementary metal oxide semiconductor (CMOS).

### SUMMARY

Aspects of the present disclosure provide a display device with a reduced or minimized thickness of an optical module.

Aspects of the present disclosure also provide a display device with improved light output efficiency.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a display panel, a first polarizing film above the display panel, a first phase retardation on the first polarizing film, and a triplet lens above the first polarizing film, and including a semi-transmissive reflective film, a first lens above the semi-transmissive reflective film, a second lens above the first lens, a second phase retardation film above the second lens, a second polarizing film above the second phase retardation film, a third lens above the second polarizing film, and a first adhesive layer between the first lens and the second lens, and having a refractive index that is greater than a refractive index of the first lens and a refractive index of the second lens.

The triplet lens may further include a second adhesive layer between the second lens and the third lens, and having a refractive index that is greater than the refractive index of the second lens and a refractive index of the third lens.

The refractive index of the first adhesive layer may be equal to or greater than about 1.7.

The refractive index of the first lens and the refractive index of the second lens may be less than about 1.7.

The triplet lens may include a first surface facing the display panel, and a second surface opposite the first surface, wherein respective average curvatures of the first surface and the second surface are different.

The first surface and the second surface may be aspherical surfaces.

The triplet lens may include plastic.

The first lens may include at least one of polymethylmethacrylate (PMMA)-based plastic or cyclic olefin copolymer (COC)-based plastic, wherein the second lens includes polycarbonate (PC)-based plastic, and wherein the third lens includes at least one of polymethylmethacrylate (PMMA)-based plastic or cyclic olefin copolymer (COC)-based plastic.

The first lens, the second lens, and the third lens may include a magnifying lens.

An electronic device may include the display device, and may further include a processor configured to provide a signal to the display device.

According to an aspect of the present disclosure, there is provided a display device including a display panel, a first polarizing film above the display panel, a first phase retardation film on the first polarizing film, a semi-transmissive reflective film above the first phase retardation film, a first lens above the semi-transmissive reflective film and including a doublet lens in which a first sub-lens and a second sub-lens are bonded by an adhesive layer having a refractive index that is greater than a refractive index of the first sub-lens and a refractive index of the second sub-lens, a second phase retardation film above the first lens, a second polarizing film above the second phase retardation film, and a second lens above the second polarizing film.

The refractive index of the adhesive layer may be equal to or greater than about 1.7.

The refractive indices of the first sub-lens and the second sub-lens may be less than about 1.7.

The first lens may include plastic.

An electronic device may include the display device, and may further include a processor configured to provide a signal to the display device.

According to an aspect of the present disclosure, there is provided a display device including a display panel, a first polarizing film above the display panel, a first phase retardation film on the first polarizing film, a semi-transmissive reflective film above the first phase retardation film, a first lens above the semi-transmissive reflective film, a second phase retardation film above the first lens, a second polarizing film above the second phase retardation film, and a second lens above the second polarizing film and including a doublet lens in which a first sub-lens and a second sub-lens are bonded by an adhesive layer having a refractive index that is greater than a refractive index of the first sub-lens and a refractive index of the second sub-lens.

The refractive index of the adhesive layer may be equal to or greater than about 1.7.

The refractive index of the first sub-lens and the refractive index of the second sub-lens may be less than about 1.7.

The second lens may include plastic.

An electronic device may include the display device, and may further include a processor configured to provide a signal to the display device.

In accordance with the display device according to one or more embodiments of the present disclosure, the thickness of the optical module may be reduced or minimized.

In accordance with the display device according to one or more embodiments of the present disclosure, the light output efficiency may be improved.

It should be noted that aspects of the present disclosure are not limited to those described above and other aspects of the present disclosure will be apparent to those skilled in the art from the following descriptions.

### BRIEF DESCRIPTION OF THE DRAWINGS

The above and other aspects of the present disclosure will become more apparent by describing in detail embodiments thereof with reference to the attached drawings, in which:

FIG. 1 is an exploded perspective view showing a display device according to one or more embodiments;

FIG. 2 is a block diagram illustrating an example of the display panel shown in FIG. 1;

FIG. 3 is an equivalent circuit diagram of a first sub-pixel according to one or more embodiments;

FIG. 4 is a layout diagram illustrating an example of a display panel according to one or more embodiments;

FIG. 5 is a layout diagram showing an example of the display area of FIG. 4;

FIG. 6 is a layout diagram showing another example of the display area of FIG. 4;

FIG. 7 is a cross-sectional view illustrating an example of a display panel taken along the line I1-I1′ of FIG. 5;

FIG. 8 is a cross-sectional view illustrating still another example of a display panel taken along the line I1-I1′ of FIG. 5;

FIG. 9 is a schematic cross-sectional view illustrating a display element layer, lenses, and an optical module of a display device according to one or more embodiments;

FIGS. 10 and 11 are cross-sectional views showing a display device according to one or more embodiments;

FIG. 12 is a graph showing lateral chromatic aberration and image height of a display device according to a comparative example;

FIG. 13 is a graph showing lateral chromatic aberration and image height of a display device according to one or more embodiments;

FIG. 14 is a schematic diagram illustrating the path and polarization state of light emitted from a display device according to one or more embodiments;

FIGS. 15 and 16 are cross-sectional views showing a display device according to one or more other embodiments;

FIGS. 17 and 18 are cross-sectional views showing a display device according to one or more other embodiments;

FIG. 19 is an exploded perspective view illustrating a head-mounted display according to one or more embodiments;

FIG. 20 is a perspective view showing an augmented reality content providing device according to one or more embodiments;

FIG. 21 is a rear exploded perspective view of the augmented reality content providing device of FIG. 20;

FIG. 22 is a front exploded perspective view of the augmented reality content providing device of FIG. 20;

FIG. 23 is a block diagram of an electronic device according to one or more embodiments; and

FIG. 24 is schematic views of electronic devices according to various embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

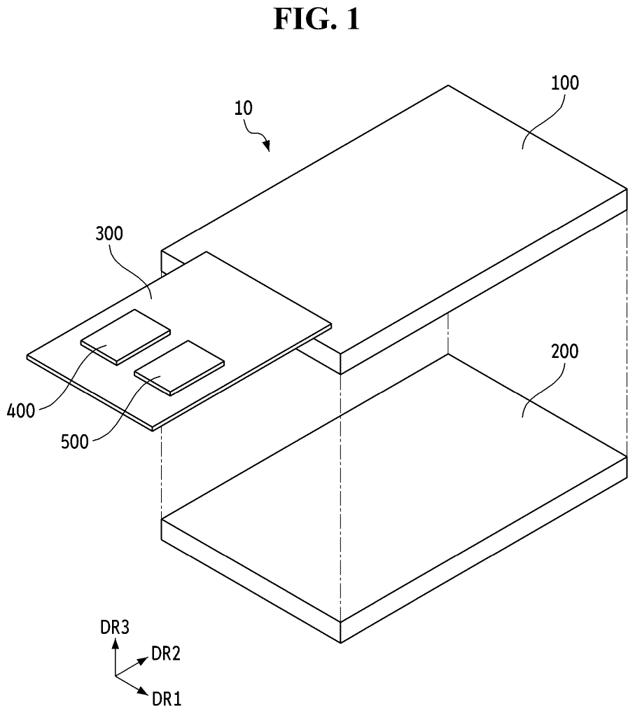

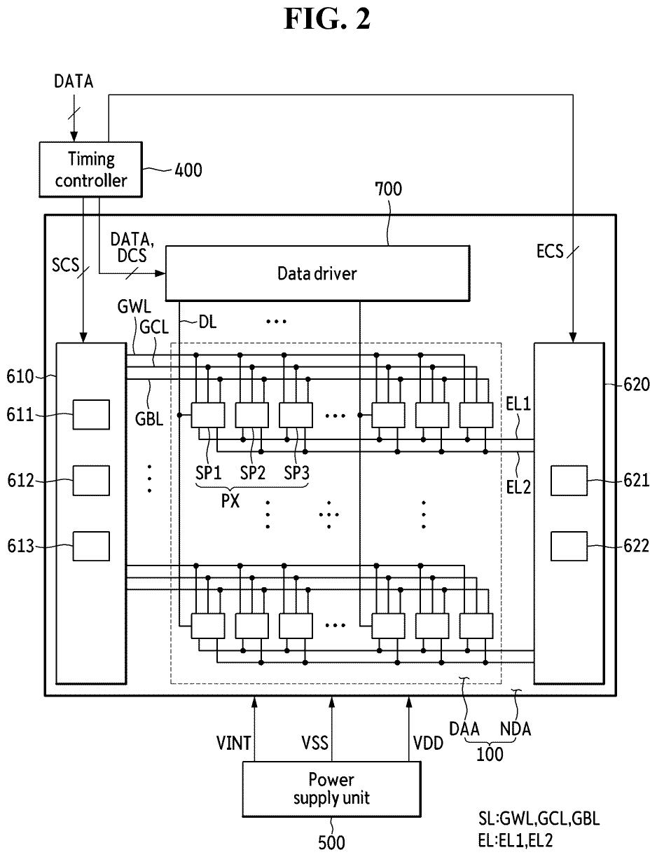

FIG. 1 is an exploded perspective view showing a display device according to one or more embodiments. FIG. 2 is a block diagram illustrating an example of the display panel shown in FIG. 1.

Referring to FIGS. 1 and 2, a display device 10 according to one or more embodiments is a device displaying a moving image or a still image. The display device 10 according to one or more embodiments may be applied to portable electronic devices, such as a mobile phone, a smartphone, a tablet personal computer, a mobile communication terminal, an electronic organizer, an electronic book, a portable multimedia player (PMP), a navigation system, an ultra mobile PC (UMPC) or the like. For example, the display device 10 according to one or more embodiments may be applied as a display unit of a television, a laptop, a monitor, a billboard, or an Internet-of-Things (IoT) terminal. Alternatively, the display device 10 according to one or more embodiments may be applied to a smart watch, a watch phone, a head-mounted display (HMD) for implementing virtual reality and augmented reality, and the like.

The display device 10 according to one or more embodiments includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape, having a short side of a first direction DR1 and a long side of a second direction DR2 crossing the first direction DR1. In the display panel 100, a corner where a short side in the first direction DR1 and a long side in the second direction DR2 meet may be right-angled or rounded with a selected curvature. The planar shape of the display panel 100 is not limited to a quadrilateral shape, and may be a shape similar to another polygonal shape, a circular shape, or an elliptical shape. The planar shape of the display device 10 may conform to the planar shape of the display panel 100, but the present disclosure is not limited thereto.

In the illustrated figure, the first direction DR1 and the second direction DR2 cross each other as horizontal directions. For example, the first direction DR1 and the second direction DR2 may be orthogonal to each other. In addition, a third direction DR3 crosses the first direction DR1 and the second direction DR2, and may be, for example, perpendicular directions orthogonal to each other. Unless otherwise defined, in the present specification, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display panel 100 includes a plurality of pixels PX, a plurality of scan lines SL, a plurality of emission control lines EL, a plurality of data lines DL, a scan driver 610, an emission driver 620, and a data driver 700. The display panel 100 may be divided into a display area DAA displaying an image and a non-display area NDA not displaying an image as shown in FIG. 2.

The plurality of pixels PX may be arranged in the display area DAA. The plurality of pixels PX may be arranged in a matrix form in the first direction DR1 and the second direction DR2. The plurality of scan lines SL and the plurality of emission control lines EL may extend in the first direction DR1, while being arranged in the second direction DR2. The plurality of data lines DL may extend in the second direction DR2, while being arranged in the first direction DR1.

The plurality of scan lines SL include a plurality of write scan lines GWL, a plurality of control scan lines GCL, and a plurality of bias scan lines GBL. The plurality of emission control lines EL include a plurality of first emission control lines ECL1 and a plurality of second emission control lines ECL2.

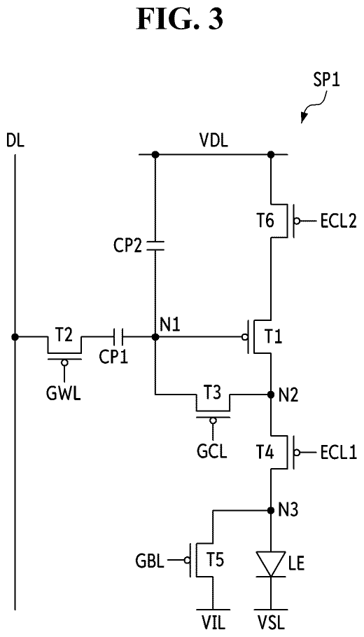

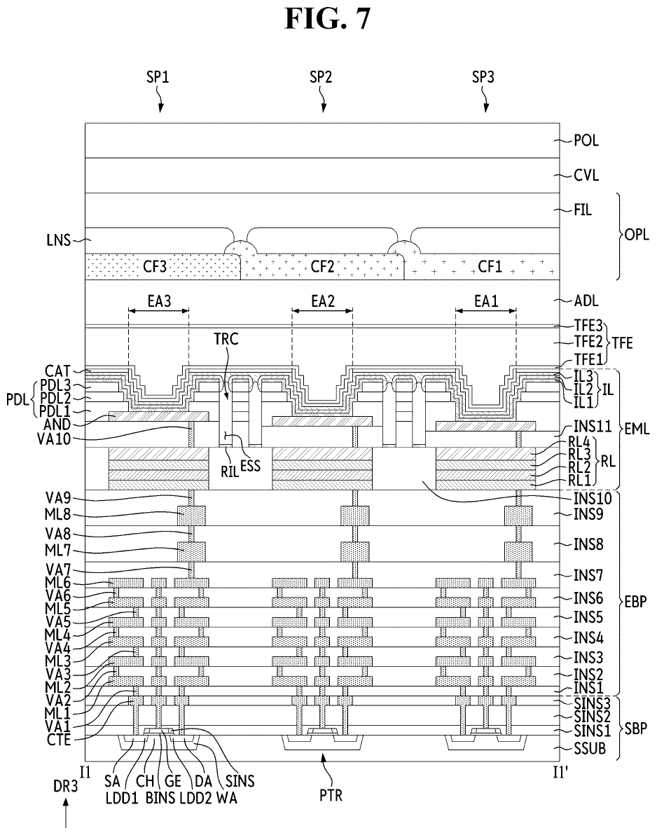

The plurality of pixels PX include a plurality of sub-pixels SP1, SP2, and SP3. The plurality of sub-pixels SP1, SP2, and SP3 may include a plurality of pixel transistors as shown in FIG. 3, and the plurality of pixel transistors may be formed by a semiconductor process and located on a semiconductor substrate SSUB (see FIG. 7). For example, the plurality of pixel transistors of the data driver 700 may be formed as complementary metal oxide semiconductor (CMOS) transistors, but the present disclosure is not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light-emitting element according to the data voltage.

The scan driver 610, the emission driver 620, and the data driver 700 may be located in the non-display area NDA.

The scan driver 610 includes a plurality of scan transistors, and the emission driver 620 includes a plurality of light-emitting transistors. The plurality of scan transistors and the plurality of light-emitting transistors may be formed on the semiconductor substrate SSUB (see FIG. 7) through a semiconductor process. For example, the plurality of scan transistors and the plurality of light-emitting transistors may be formed as CMOS transistors, but the present disclosure is not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan-timing control signal SCS from the timing control circuit 400. The write scan signal output unit 611 may generate write scan signals according to the scan-timing control signal SCS of the timing control circuit 400 and output them sequentially to the write scan lines GWL. The control scan signal output unit 612 may generate control scan signals in response to the scan-timing control signal SCS and sequentially output them to the control scan lines GCL. The bias scan signal output unit 613 may generate bias scan signals according to the scan-timing control signal SCS and output them sequentially to the bias scan lines GBL.

The emission driver 620 includes a first emission control driver 621 and a second emission control driver 622. Each of the first emission control driver 621 and the second emission control driver 622 may receive an emission-timing control signal ECS from the timing control circuit 400. The first emission control driver 621 may generate first emission control signals according to the emission-timing control signal ECS and sequentially output them to the first emission control lines ECL1. The second emission control driver 622 may generate second emission control signals according to the emission-timing control signal ECS and sequentially output them to the second emission control lines EL2.

The data driver 700 may include a plurality of data transistors, and the plurality of data transistors may be formed on the semiconductor substrate SSUB (see FIG. 7) through a semiconductor process. For example, the plurality of data transistors may be formed as CMOS transistors, but the present disclosure is not limited thereto.

The data driver 700 may receive digital video data DATA and a data-timing control signal DCS from the timing control circuit 400. The data driver 700 converts the digital video data DATA into analog data voltages according to the data-timing control signal DCS and outputs the analog data voltages to data lines DL. In this case, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be located on one surface, e.g., the rear surface, of the display panel 100. The heat dissipation layer 200 serves to dissipate heat generated from the display panel 100. The heat dissipation layer 200 may include a metal layer having high thermal conductivity, such as graphite, silver (Ag), copper (Cu), or aluminum (Al).

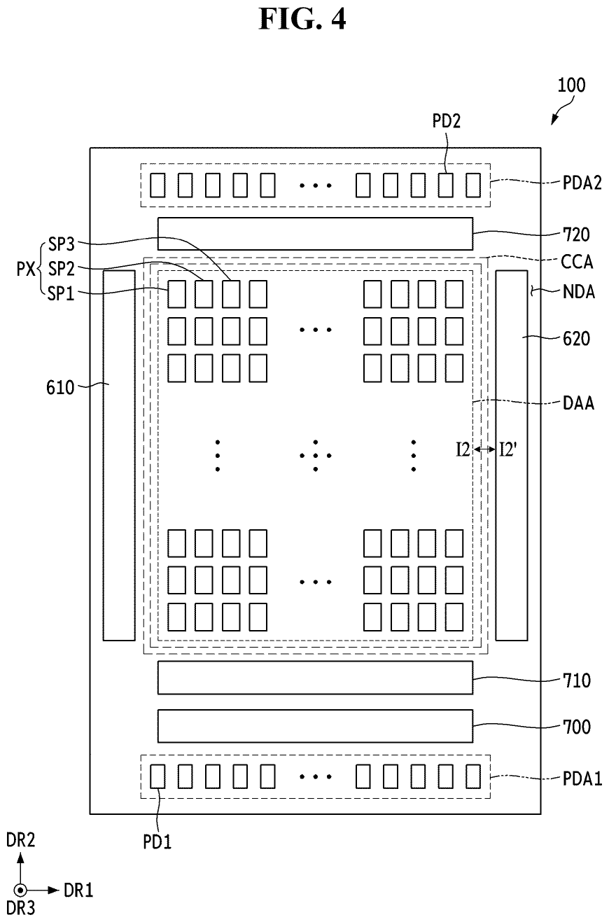

The circuit board 300 may be electrically connected to a plurality of first pads PD1 (see FIG. 4) of a first pad portion PDA1 (see FIG. 4) of the display panel 100 by using a conductive adhesive member, such as an anisotropic conductive film. The circuit board 300 may be a flexible printed circuit board with a flexible material, or a flexible film. Although the circuit board 300 is illustrated in FIG. 1 as being unfolded, the circuit board 300 may be bent. In this case, one end of the circuit board 300 may be located on the rear surface of the display panel 100 and/or the rear surface of the heat dissipation layer 200. The other end of the circuit board 300 may be connected to the plurality of first pads PD1 (see FIG. 4) of the first pad portion PDA1 (see FIG. 4) of the display panel 100 by using a conductive adhesive member. One end of the circuit board 300 may be an opposite end of the other end of the circuit board 300.

The timing control circuit 400 may receive digital video data and timing signals inputted from the outside. The timing control circuit 400 may generate the scan-timing control signal SCS, the emission-timing control signal ECS, and the data-timing control signal DCS for controlling the display panel 100 in response to the timing signals. The timing control circuit 400 may output the scan-timing control signal SCS to the scan driver 610, and output the emission-timing control signal ECS to the emission driver 620. The timing control circuit 400 may output the digital video data and the data-timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT, and may supply them to the display panel 100. The first driving voltage VSS, the second driving voltage VDD, and the third driving voltage VINT will be described later in conjunction with FIG. 3.

Each of the timing control circuit 400 and the power supply circuit 500 may be formed as an integrated circuit (IC) and attached to one surface of the circuit board 300. In this case, the scan-timing control signal SCS, the emission-timing control signal ECS, the digital video data DATA, and the data-timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

Alternatively, each of the timing control circuit 400 and the power supply circuit 500 may be located in the non-display area NDA of the display panel 100, similarly to the scan driver 610, the emission driver 620, and the data driver 700. In this case, the timing control circuit 400 may include a plurality of timing transistors, and each power supply circuit 500 may include a plurality of power transistors. The plurality of timing transistors and the plurality of power transistors may be formed on the semiconductor substrate SSUB (see FIG. 7) through a semiconductor process. For example, the plurality of timing transistors and the plurality of power transistors may be formed as CMOS transistors, but the present disclosure is not limited thereto. Each of the timing control circuit 400 and the power supply circuit 500 may be located between the data driver 700 and the first pad portion PDA1 (see FIG. 4).

FIG. 3 is an equivalent circuit diagram of a first sub-pixel according to one or more embodiments.

Referring to FIG. 3, a first sub-pixel SP1 may be connected to the write scan line GWL, the control scan line GCL, the bias scan line GBL, the first emission control line ECL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied.

The first sub-pixel SP1 includes a plurality of transistors T1 to T6, a light-emitting element LE, a first capacitor CP1, and a second capacitor CP2.

The light-emitting element LE emits light in response to a driving current flowing through the channel of the first transistor T1. The emission amount of the light-emitting element LE may be proportional to the driving current Ids. The first electrode of the light-emitting element LE may be an anode electrode, and the second electrode of the light-emitting element LE may be a cathode electrode. The light-emitting element LE may be an organic light-emitting diode including a first electrode, a second electrode, and an organic light-emitting layer located between the first electrode and the second electrode, but the present disclosure is not limited thereto. For example, the light-emitting element LE may be an inorganic light-emitting element including a first electrode, a second electrode, and an inorganic semiconductor located between the first electrode and the second electrode, in which case the light-emitting element LE may be a micro light-emitting diode.

The first transistor T1 may be a driving transistor that controls a source-drain current Ids (hereinafter referred to as “driving current”) flowing between the source electrode and the drain electrode according to a voltage applied to the gate electrode.

A second transistor T2 may be located between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be located between a first node N1 and a second node N2. The third transistor T3 is turned on by the write control signal of the control scan line GCL to connect the first node N1 to the second node N2. For this reason, when the gate electrode and the source electrode of the first transistor T1 are connected, the first transistor T1 may operate like a diode.

The fourth transistor T4 may be connected between the second node N2 and a third node N3. The fourth transistor T4 is turned on by the first emission control signal of the first emission control line ECL1 to connect the second node N2 to the third node N3. Accordingly, the driving current of the first transistor T1 may be supplied to the light-emitting element LE. A fifth transistor T5 may be located between the third node N3 and the third driving voltage line VIL. The fifth transistor T5 is turned on by the bias scan signal of the bias scan line GBL to connect the third node N3 to the third driving voltage line VIL. Accordingly, the third driving voltage VINT of the third driving voltage line VIL may be applied to the first electrode of the light-emitting element LE.

The sixth transistor T6 may be located between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 is formed between the first node N1 and the drain electrode of the second transistor T2. The second capacitor CP2 is formed between the gate electrode of the first transistor T1 and the second driving voltage line VDL.

Each of the first to sixth transistors T1 to T6 may be a metal-oxide-semiconductor field effect transistor (MOSFET). For example, each of the first to sixth transistors T1 to T6 may be a p-type MOSFET, but the present disclosure is not limited thereto. Each of the first to sixth transistors T1 to T6 may be an n-type MOSFET. Alternatively, some of the first to sixth transistors T1 to T6 may be p-type MOSFETs, and each of the remaining transistors may be an n-type MOSFET.

Although it is illustrated in FIG. 3 that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is not repeated in the present disclosure.

FIG. 4 is a layout diagram illustrating an example of a display panel according to one or more embodiments.

Referring to FIG. 4, the display area DAA of the display panel 100 according to one or more embodiments includes the plurality of pixels PX arranged in a matrix form. The non-display area NDA of the display panel 100 according to one or more embodiments includes the scan driver 610, the emission driver 620, the data driver 700, a first distribution circuit 710, a second distribution circuit 720, the first pad portion PDA1, and a second pad portion PDA2.

The scan driver 610 may be located on a first side of the display area DAA, and the emission driver 620 may be located on a second side of the display area DAA. For example, the scan driver 610 may be located on one side of the display area DAA in the first direction DR1, and the emission driver 620 may be located on the other side of the display area DAA in the first direction DR1. However, the present disclosure is not limited thereto, and the scan driver 610 and the emission driver 620 may be located on both the first side and the second side of the display area DAA.

The first pad portion PDA1 may include the plurality of first pads PD1 connected to pads or bumps of the circuit board 300 through a conductive adhesive member. The first pad portion PDA1 may be located on a third side of the display area DAA. For example, the first pad portion PDA1 may be located on one side of the display area DAA in the second direction DR2. The first pad portion PDA1 may be located outside the data driver 700 in the second direction DR2.

The second pad portion PDA2 may include a plurality of second pads PD2 corresponding to inspection pads that test whether the display panel 100 operates normally. The plurality of second pads PD2 may be connected to a jig or a probe pin during an inspection process, or may be connected to a circuit board for inspection. The circuit board for inspection may be a printed circuit board including a rigid material or a flexible printed circuit board including a flexible material.

The second pad portion PDA2 may be located on a fourth side of the display area DAA. For example, the second pad portion PDA2 may be located on the other side of the display area DAA in the second direction DR2. The second pad portion PDA2 may be located outside the second distribution circuit 720 in the second direction DR2.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (P is a positive integer of 2 or more) data lines DL, and as a result, the number of the plurality of first pads PD1 may be reduced. The first distribution circuit 710 may be located on the third side of the display area DAA of the display panel 100. For example, the first distribution circuit 710 may be located on one side of the display area DAA in the second direction DR2.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be located on the fourth side of the display area DAA of the display panel 100. For example, the second distribution circuit 720 may be located on the other side of the display area DAA in the second direction DR2.

A cathode connection portion CCA may be a region in which a second electrode CAT (see FIG. 7) of a display element layer EML (see FIG. 7) is connected to the first driving voltage line VSL of the non-display area NDA. The cathode connection portion CCA may be located outside at least one side of the display area DAA. For example, the cathode connection portion CCA may be located outside at least on one side among the left side, the right side, the upper side, and the lower side of the display area DAA. Alternatively, the cathode connection portion CCA may be located to surround the display area DAA as shown in FIG. 4 to reduce or minimize a deviation in the first driving voltage VSS due to a voltage drop (IR drop) or voltage rise (IR rising) of the second electrode CAT in the display area DAA.

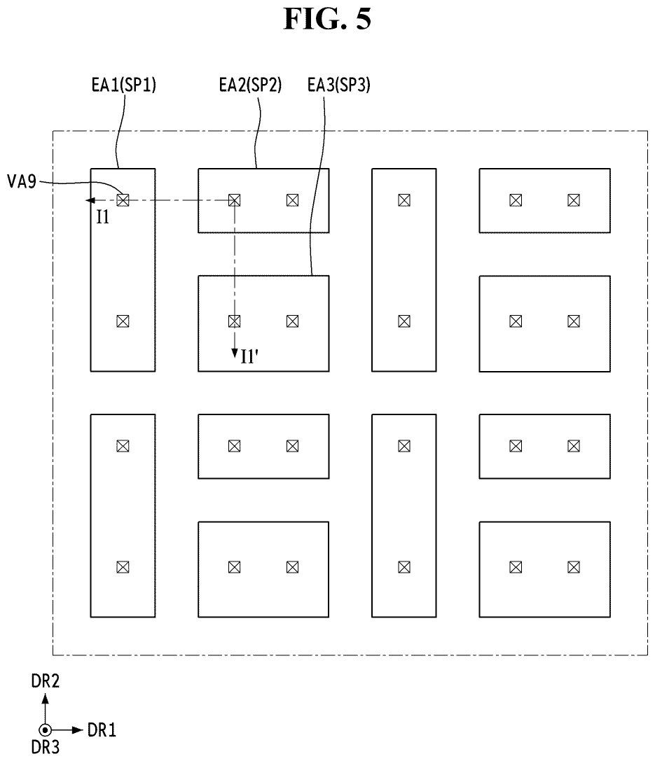

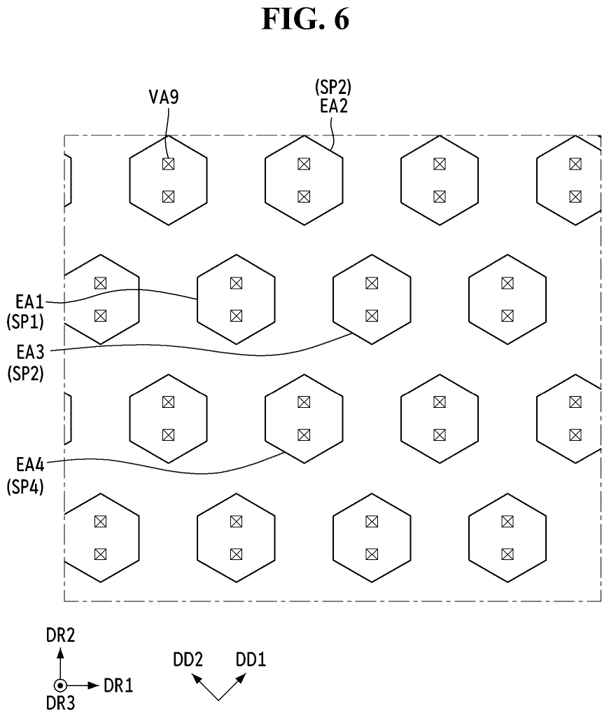

FIG. 5 is a layout diagram showing an example of the display area of FIG. 4. FIG. 6 is a layout diagram showing another example of the display area of FIG. 4.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in plan view, a quadrilateral or hexagonal shape as shown in FIGS. 5 and 6, but the present disclosure is not limited thereto. The first emission area EA1, the second emission area EA2, and the third emission area EA3 may have a polygonal shape other than a quadrangle or hexagon, a circular shape, an elliptical shape, or an atypical shape in plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different.

Alternatively, as shown in FIG. 6, the emission areas EA1, EA2, EA3, and EA4 may have a hexagonal shape in plan view. In this case, the first emission area EA1 and the third emission area EA3 may be adjacent in the first direction DR1, and the second emission area EA2 and the fourth emission area EA4 may be adjacent in the second direction DR2. Additionally, the first emission area EA1 and the second emission area EA2 may be adjacent in a first diagonal direction DD1, and the second emission area EA2 and the third emission area EA3 may be adjacent in a second diagonal direction DD2. Additionally, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2, and may refer to a direction inclined by 45 degrees with respect to the first direction DR1 and the second direction DR2, and the second diagonal direction DD2 may be a direction perpendicular to the first diagonal direction DD1.

The first sub-pixel SP1 may emit first light, the second sub-pixel SP2 may emit second light, and the third sub-pixel SP3 may emit third light. Here, the first light may be light of a blue wavelength band, the second light may be light of a green wavelength band, and the third light may be light of a red wavelength band. For example, the blue wavelength band may be a wavelength band of light whose main peak wavelength is in the range of approximately 370 nm to approximately 460 nm, the green wavelength band may be a wavelength band of light whose main peak wavelength is in the range of approximately 480 nm to approximately 560 nm, and the red wavelength band may be a wavelength band of light whose main peak wavelength is in the range of approximately 600 nm to approximately 750 nm.

Each of the plurality of pixels PX may include three emission areas EA1, EA2, and EA3 as shown in FIG. 5, or may include four emission areas EA1, EA2, EA3, and EA4 as shown in FIG. 6. In this case, the fourth emission area EA4 may emit the same second light as the second emission area EA2, but the present disclosure is not limited thereto.

The emission areas of the plurality of pixels PX may be arranged in a stripe structure in which the emission areas are arranged in the first direction DR1, a PenTile® structure (PenTile® being a registered trademark of Samsung Display Co., Ltd., Republic of Korea) in which the emission areas EA1, EA2, EA3, and EA4 are arranged in a rhombus shape, or a hexagonal structure in which the emission areas each having a hexagonal shape are arranged as shown in FIG. 6.

FIG. 7 is a cross-sectional view illustrating an example of a display panel taken along the line I1-I1′ of FIG. 5.

Referring to FIG. 7, the display panel 100 includes a semiconductor backplane SBP, a light-emitting element backplane EBP, the display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 3.

The semiconductor substrate SSUB may be a silicon substrate, a germanium substrate, or a silicon-germanium substrate. The semiconductor substrate SSUB may be a substrate doped with a first type impurity. A plurality of well regions WA may be located on the top surface of the semiconductor substrate SSUB (as used herein, “located on” may mean “above”). The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA includes a source region SA corresponding to the source electrode of the pixel transistor PTR, a drain region DA corresponding to the drain electrode, and a channel region CH located between the source region SA and the drain region DA.

A lower insulating film BINS may be located between a gate electrode GE and the well region WA. A side insulating film SINS may be located on the side surface of the gate electrode GE. The side insulating film SINS may be located on the lower insulating film BINS.

Each of the source region SA and the drain region DA may be a region doped with the first type impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be located on one side of the gate electrode GE, and the drain region DA may be located on the other side of the gate electrode GE.

Each of the plurality of well regions WA further includes a first low-concentration impurity region LDD1 located between the channel region CH and the source region SA, and a second low-concentration impurity region LDD2 located between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, which may result in an increase of the length of the channel region CH of each of the pixel transistors PTR.

A first semiconductor insulating film SINS1 may be located on the semiconductor substrate SSUB. A second semiconductor insulating film SINS2 may be located on the first semiconductor insulating film SINS1.

The plurality of contact terminals CTE may be located on the second semiconductor insulating film SINS2. Each of the plurality of contact terminals CTE may be connected to any one of the gate electrode GE, the source region SA, or the drain region DA of each of the pixel transistors PTR through a hole penetrating the first semiconductor insulating film SINS1 and the second semiconductor insulating film SINS2. The plurality of contact terminals CTE may include any one of copper (Cu), aluminum (Al), tungsten (W), molybdenum (Mo), chromium (Cr), gold (Au), titanium (Ti), nickel (Ni), or neodymium (Nd), or an alloy including any one of them.

A third semiconductor insulating film SINS3 may be located on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may include silicon carbonitride (SiCN) or a silicon oxide (SiOₓ)-based inorganic film, but the present disclosure is not limited thereto.

The semiconductor substrate SSUB may be replaced with a glass substrate or a polymer resin substrate, such as polyimide. In this case, thin film transistors may be located on the glass substrate or the polymer resin substrate. The glass substrate may be a rigid substrate that does not bend, and the polymer resin substrate may be a flexible substrate that can be bent or curved.

The light-emitting element backplane EBP includes a plurality of conductive layers ML1 to ML8, a plurality of vias VA1 to VA9, and a plurality of insulating films INS1 to INS11. In addition, the light-emitting element backplane EBP includes a plurality of insulating films INS1 to INS9 located between the first to eighth conductive layers ML1 to ML8.

First to eighth insulating films INS1 to INS8 serve to insulate the first to eighth conductive layers ML1 to ML8. The first to eighth conductive layers ML1 to ML8 serve to connect the plurality of contact terminals CTE exposed from the semiconductor backplane SBP to thereby implement the circuit of the first sub-pixel SP1 shown in FIG. 3.

For example, the first to sixth transistors T1 to T6 are merely formed in the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and a first electrode AND of the light-emitting element LE is also accomplished through the first to eighth conductive layers ML1 to ML8.

The first to eighth conductive layers ML1 to ML8 and the first to eighth vias VA1 to VA8 may include substantially the same material. The first to eighth conductive layers ML1 to ML8 and the first to eighth vias VA1 to VA8 may include any one of copper (Cu), aluminum (Al), tungsten (W), molybdenum (Mo), chromium (Cr), gold (Au), titanium (Ti), nickel (Ni), or neodymium (Nd), or an alloy including any one of them. The first to eighth vias VA1 to VA8 may include substantially the same material. The first to eighth insulating films INS1 to INS8 may be formed as silicon oxide (SiOx)-based inorganic films, but the present disclosure is not limited thereto.

A ninth insulating film INS9 may be located on the eighth insulating film INS8 and the eighth conductive layer ML8. The ninth insulating film INS9 may be formed as a silicon oxide (SiOₓ)-based inorganic film, but the present disclosure is not limited thereto.

Each of the ninth vias VA9 may penetrate the ninth insulating film INS9 and may be connected to the exposed eighth conductive layer ML8. The ninth vias VA9 may include any one of copper (Cu), aluminum (Al), tungsten (W), molybdenum (Mo), chromium (Cr), gold (Au), titanium (Ti), nickel (Ni), or neodymium (Nd), or an alloy including any one of them.

The display element layer EML may be located on the light-emitting element backplane EBP. The display element layer EML may include tenth and eleventh insulating films INS10 and INS11, a reflective electrode RL, the first electrodes AND, a light-emitting stack IL, the second electrode CAT, a pixel-defining film PDL, and a plurality of trenches TRC.

The reflective electrode RL may be located on the ninth insulating film INS9. The reflective electrode RL may include at least one reflective electrode RL1, RL2, RL3, and RL4. For example, the reflective electrode RL may include first to fourth reflective electrodes RL1, RL2, RL3, and RL4 as shown in FIG. 7.

The first reflective electrodes RL1 may be located on the ninth interlayer insulating film INS9, and may be connected to the ninth via VA9. Each of the second reflective electrodes RL2 may be located on the first reflective electrode RL1 corresponding thereto. Each of the third reflective electrodes RL3 may be located on the second reflective electrode RL2 corresponding thereto. Each of the fourth reflective electrodes RL4 may be located on the third reflective electrode RL3 corresponding thereto.

Because the second reflective electrode RL2 is an electrode that substantially reflects light from the light-emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may include any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first reflective electrodes RL1 may include titanium nitride (TiN), the second reflective electrodes RL2 may include aluminum (Al), the third reflective electrodes RL3 may include titanium nitride (TiN), and the fourth reflective electrodes RL4 may include titanium (Ti).

The tenth interlayer insulating film INS10 may be located on the ninth interlayer insulating film INS9. The tenth interlayer insulating film INS10 may be located between the reflective electrodes RL adjacent to each other. The tenth interlayer insulating film INS10 may be a film for flattening a stepped portion caused by the reflective electrodes RL. The eleventh interlayer insulating film INS11 may be located on the tenth interlayer insulating film INS10 and the reflective electrode RL.

The tenth interlayer insulating film INS10 and the eleventh interlayer insulating film INS11 may be formed as silicon oxide (SiOₓ)-based inorganic films, but the present disclosure is not limited thereto.

The eleventh interlayer insulating film INS11 may be an optical auxiliary layer for adjusting the resonance distance of light emitted from the light-emitting stack IL in at least one of the first sub-pixel SP1, the second sub-pixel SP2, or the third sub-pixel SP3. The thickness of the eleventh interlayer insulating film INS11 may be different in the first sub-pixel SP1, the second sub-pixel SP2, and the third sub-pixel SP3. That is, to adjust a distance from the reflective electrode RL to the second electrode CAT according to a main wavelength of light emitted from each of the first sub-pixel SP1, the second sub-pixel SP2, and the third sub-pixel SP3, the thickness of the eleventh interlayer insulating film INS11 may be set for each of the first sub-pixel SP1, the second sub-pixel SP2, and the third sub-pixel SP3.

For example, as shown in FIG. 7, the thickness of the eleventh interlayer insulating film INS11 in the first sub-pixel SP1 may be greater than the thickness of the eleventh interlayer insulating film INS11 in the second sub-pixel SP2, which may be greater than the thickness of the eleventh interlayer insulating film INS11 in the third sub-pixel SP3. In this case, the distance between the first electrode AND and the reflective electrode RL in the first sub-pixel SP1 is greater than the distance between the first electrode AND and the reflective electrode RL in the second sub-pixel SP2. In addition, the distance between the first electrode AND and the reflective electrode RL in the second sub-pixel SP2 is greater than the distance between the first electrode AND and the reflective electrode RL in the third sub-pixel SP3.

Each of the tenth vias VA10 may penetrate the eleventh interlayer insulating film INS11 and may be connected to the exposed ninth metal layer ML9. The tenth vias VA10 may include any one of copper (Cu), aluminum (Al), tungsten (W), molybdenum (Mo), chromium (Cr), gold (Au), titanium (Ti), nickel (Ni), or neodymium (Nd), or an alloy including any one of them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light-emitting elements LE may be located on the eleventh interlayer insulating film INS11 and connected to the tenth via VA10. The first electrode AND of each of the light-emitting elements LE may be connected to the drain region DA or source region SA of the pixel transistor PTR through the tenth via VA10, the reflective electrode RL, the first to ninth vias VA1 to VA9, the first to eighth metal layers ML1 to ML8, and the contact terminal CTE. The first electrode AND of each of the light-emitting elements LE may include any one of copper (Cu), aluminum (Al), tungsten (W), molybdenum (Mo), chromium (Cr), gold (Au), titanium (Ti), nickel (Ni), or neodymium (Nd), or an alloy including any one of them. For example, the first electrode AND of each of the light-emitting elements LE may be titanium nitride (TiN).

The pixel-defining film PDL may be located on a part of the first electrode AND of each of the light-emitting elements LE. The pixel-defining film PDL may cover the edge of the first electrode AND of each of the light-emitting elements LE. The pixel-defining film PDL may partition the first emission areas EA1, the second emission areas EA2, and the third emission areas EA3. Each of the first emission area EA1, the second emission area EA2, and the third emission area EA3 may be an area where the light-emitting element LE including the first electrode AND, the light-emitting stack IL, and the second electrode CAT is located.

The first emission area EA1 may be defined as an area in which the first electrode AND, the light-emitting stack IL, and the second electrode CAT are sequentially stacked in the first sub-pixel SP1 to emit light. The second emission area EA2 may be defined as an area in which the first electrode AND, the light-emitting stack IL, and the second electrode CAT are sequentially stacked in the second sub-pixel SP2 to emit light. The third emission area EA3 may be defined as an area in which the first electrode AND, the light-emitting stack IL, and the second electrode CAT are sequentially stacked in the third sub-pixel SP3 to emit light.

The pixel-defining film PDL may include first to third pixel-defining films PDL1, PDL2, and PDL3. The first pixel-defining film PDL1 may be located on the edge of the first electrode AND of each of the light-emitting elements LE, the second pixel-defining film PDL2 may be located on the first pixel-defining film PDL1, and the third pixel-defining film PDL3 may be located on the second pixel-defining film PDL2. The first pixel-defining film PDL1, the second pixel-defining film PDL2, and the third pixel-defining film PDL3 may be formed as silicon oxide (SiOₓ)-based inorganic films. Alternatively, the first pixel-defining film PDL1 and the third pixel-defining film PDL3 may be formed as silicon nitride (SiNₓ)-based inorganic films, whereas the second pixel-defining film PDL2 may be formed as a silicon oxide (SiOₓ)-based inorganic film. The first pixel-defining film PDL1, the second pixel-defining film PDL2, and the third pixel-defining film PDL3 may each have a thickness of about 500 Å.

In order to reduce or prevent the likelihood of the first encapsulation inorganic film TFE1 being cut off due to the step coverage, the first pixel-defining film PDL1, the second pixel-defining film PDL2, and the third pixel-defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel-defining film PDL1, the second pixel-defining film PDL2, and the third pixel-defining film PDL3. The eleventh interlayer insulating film INS11 may be at least partially recessed at each of the plurality of trenches TRC.

At least one trench TRC may be located between the neighboring sub-pixels SP1, SP2, and SP3. Although FIG. 7 illustrates that two trenches TRC are located between the neighboring sub-pixels SP1, SP2, and SP3, the present disclosure is not limited thereto.

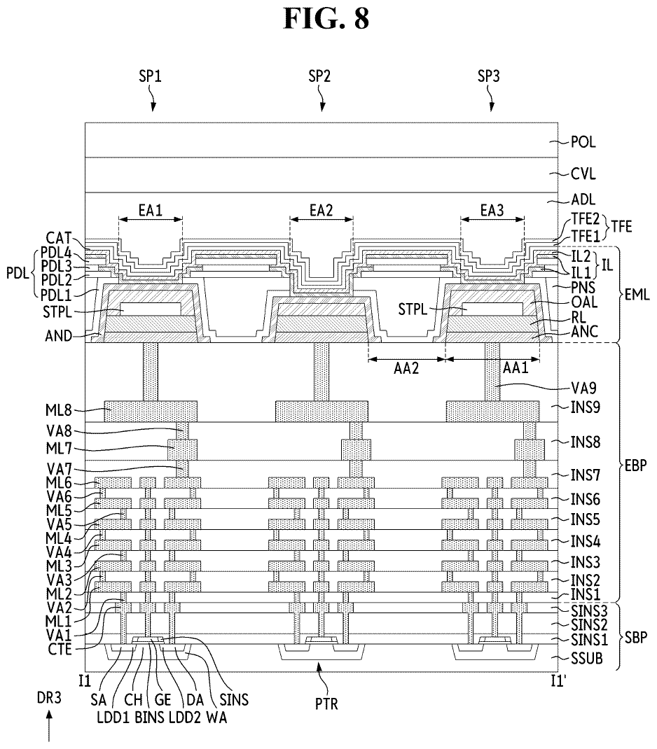

The light-emitting stack IL may include a plurality of stack layers IL1, IL2, and IL3. FIG. 7 illustrates that the light-emitting stack IL has a three-tandem structure including a first stack layer IL1, a second stack layer IL2, and a third stack layer IL3, but the present disclosure is not limited thereto. For example, the light-emitting stack IL may have a two-tandem structure including two stack layers as shown in FIG. 8.

In the three-tandem structure, the light-emitting stack IL may have a tandem structure including a plurality of stack layers IL1, IL2, and IL3 that emit different lights. For example, the light-emitting stack IL may include the first stack layer IL1 that emits the first light, the second stack layer IL2 that emits the second light, and the third stack layer IL3 that emits the third light. The first stack layer IL1, the second stack layer IL2, and the third stack layer IL3 may be sequentially stacked.

The first stack layer IL1 may have a structure in which a first hole transport layer, a first light-emitting layer that emits the first light, and a first electron transport layer are sequentially stacked. The second stack layer IL2 may have a structure in which a second hole transport layer, a second light-emitting layer that emits the second light, and a second electron transport layer are sequentially stacked. The third stack layer IL3 may have a structure in which a third hole transport layer, a third light-emitting layer that emits the third light, and a third electron transport layer are sequentially stacked.

A first charge generation layer for supplying charges to the second stack layer IL2 and for supplying electrons to the first stack layer IL1 may be located between the first stack layer IL1 and the second stack layer IL2. The first charge generation layer may include an n-type charge generation layer that supplies electrons to the first stack layer IL1 and a p-type charge generation layer that supplies holes to the second stack layer IL2. The n-type charge generation layer may include a dopant of a metal material.

A second charge generation layer for supplying charges to the third stack layer IL3 and for supplying electrons to the second stack layer IL2 may be located between the second stack layer IL2 and the third stack layer IL3. The second charge generation layer may include an n-type charge generation layer that supplies electrons to the second stack layer IL2 and a p-type charge generation layer that supplies holes to the third stack layer IL3.

The first stack layer IL1 may be located on the first electrodes AND and the pixel-defining film PDL, and a residual film RIL located on the bottom surface of each trench TRC may be the same material as the first stack layer IL1. Due to the trench TRC, the first stack layer IL1 may be cut off between the neighboring sub-pixels SP1, SP2, and SP3. The second stack layer IL2 may be located on the first stack layer IL1. Due to the trench TRC, the second stack layer IL2 may be cut off between the neighboring sub-pixels SP1, SP2, and SP3. A cavity ESS or an empty space may be located between the residual film RIL and the second stack layer IL2 in the trench TRC. The third stack layer IL3 may be located on the second stack layer IL2. The third stack layer IL3 is not cut off by the trench TRC and may be located to cover the second stack layer IL2 in each of the trenches TRC.

In the three-tandem structure, each of the plurality of trenches TRC may be a structure for cutting off the first to third hole transport layers, the first charge generation layer, and the second charge generation layer of the first to third stack layers IL1, IL2, and IL3 of the display element layer EML between the neighboring sub-pixels SP1, SP2, and SP3. In addition, in the two-tandem structure, each of the plurality of trenches TRC may be a structure for cutting off the charge generation layer and the lower stack layer located between the lower stack layer and the upper stack layer.

In order to stably cut off the first and second stack layers IL1 and IL2 of the display element layer EML between the neighboring sub-pixels SP1, SP2, and SP3, the height of each of the plurality of trenches TRC may be greater than the height of the pixel-defining film PDL. The height of each of the plurality of trenches TRC refers to the length of each of the plurality of trenches TRC in the third direction DR3. The height of the pixel-defining film PDL refers to the length of the pixel-defining film PDL in the third direction DR3. In order to cut off the charge generation layers and the hole transport layers of the light-emitting stack IL of the display element layer EML between the neighboring sub-pixels SP1, SP2, and SP3, a different structure may be present instead of the trench TRC. For example, instead of the trench TRC, a reverse tapered partition wall may be located on the pixel-defining film PDL.

In addition, FIG. 7 illustrates that the light-emitting stack IL that emits light is located in the first emission area EA1, the second emission area EA2, and the third emission area EA3, but the present disclosure is not limited thereto. For example, instead of the light-emitting stack IL, the first light-emitting layer may be located in the first emission area EA1, and may be omitted from the second emission area EA2 and the third emission area EA3. Furthermore, the second light-emitting layer may be located in the second emission area EA2 and may be omitted from the first emission area EA1 and the third emission area EA3. Furthermore, the third light-emitting layer may be located in the third emission area EA3 and may be omitted from the first emission area EA1 and the second emission area EA2. In this case, first to third color filters CF1, CF2, and CF3 of the optical layer OPL may be omitted.

The second electrode CAT may be located on the light-emitting stack IL. The second electrode CAT may be located on the third stack layer IL3 in each of the plurality of trenches TRC. The second electrode CAT may include a transparent conductive material (TCO), such as ITO or IZO that can transmit light or a semi-transmissive conductive material, such as magnesium (Mg), silver (Ag), or an alloy of Mg and Ag. When the second electrode CAT includes a semi-transmissive conductive material, the light emission efficiency may be improved in each of the first to third sub-pixels SP1, SP2, and SP3 due to a micro-cavity effect.

The encapsulation layer TFE may be located on the display element layer EML. The encapsulation layer TFE may include at least one inorganic film TFE1 and TFE2 to reduce or prevent oxygen or moisture from permeating into the display element layer EML. The first encapsulation inorganic film TFE1 may be located on the second electrode CAT, and the second encapsulation inorganic film TFE2 may be located on the first encapsulation inorganic film TFE1. The first encapsulation inorganic film TFE1 and the second encapsulation inorganic film TFE3 may be formed as multiple films in which one or more inorganic films of silicon nitride (SiNₓ), silicon oxynitride (SiON), silicon oxide (SiOₓ), titanium oxide (TiOₓ), and aluminum oxide (AlOₓ) layers are alternately stacked.

In addition, the encapsulation layer TFE may include at least one organic film to protect the display element layer EML from foreign substances, such as dust. The at least one organic film of the encapsulation layer TFE may be located between the first encapsulation inorganic film TFE1 and the second encapsulation inorganic film TFE2. The at least one organic film of the encapsulation layer TFE may be a monomer. Alternatively, at least one organic film of the encapsulation layer TFE may be an organic film, such as acryl resin, epoxy resin, phenolic resin, polyamide resin, polyimide resin or the like.

An adhesive layer ADL may be a layer for bonding the encapsulation layer TFE to the optical layer OPL. The adhesive layer ADL may be a double-sided adhesive member. In addition, the adhesive layer ADL may be a transparent adhesive member, such as a transparent adhesive or a transparent adhesive resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be located on the adhesive layer ADL.

The first color filter CF1 may overlap the first emission area EA1 of the first sub-pixel SP1. The first color filter CF1 may transmit light of a first color, e.g., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of a second color, e.g., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of a third color, e.g., light of a red wavelength band. The red wavelength band may be about 600 nm to about 750 nm. Thus, the third color filter CF3 may transmit light of the third color among light emitted from the third emission area EA3.

The plurality of lenses LNS may be located on the first color filter CF1, the second color filter CF2, and the third color filter CF3, respectively. Each of the plurality of lenses LNS may be a structure for increasing the proportion of light directed to the front of the display device 10. Each of the plurality of lenses LNS may have a cross-sectional shape that is convex in an upward direction.

The filling layer FIL may be located on the plurality of lenses LNS. The filling layer FIL may have a selected refractive index such that light travels in the third direction DR3 at an interface between the filling layer FIL and the plurality of lenses LNS. Further, the filling layer FIL may be a planarization layer. The filling layer FIL may be an organic film, such as acrylic resin, epoxy resin, phenolic resin, polyamide resin, or polyimide resin.

The cover layer CVL may be located on the filling layer FIL. The cover layer CVL may be a glass substrate or a polymer resin. When the cover layer CVL is a glass substrate, it may be attached onto the filling layer FIL. In this case, the filling layer FIL may serve to bond the cover layer CVL. When the cover layer CVL is a glass substrate, it may serve as an encapsulation substrate. When the cover layer CVL is a polymer resin, it may be directly applied onto the filling layer FIL.

The polarizing plate POL may be located on one surface of the cover layer CVL. The polarizing plate POL may be a structure for reducing or preventing visibility degradation caused by reflection of external light. The polarizing plate POL may include a linear polarizing plate and a phase retardation film. For example, the phase retardation film may be a λ/4 plate (quarter-wave plate), but the present disclosure is not limited thereto. However, when visibility degradation caused by reflection of external light is sufficiently overcome by the first to third color filters CF1, CF2, and CF3, the polarizing plate POL may be omitted.

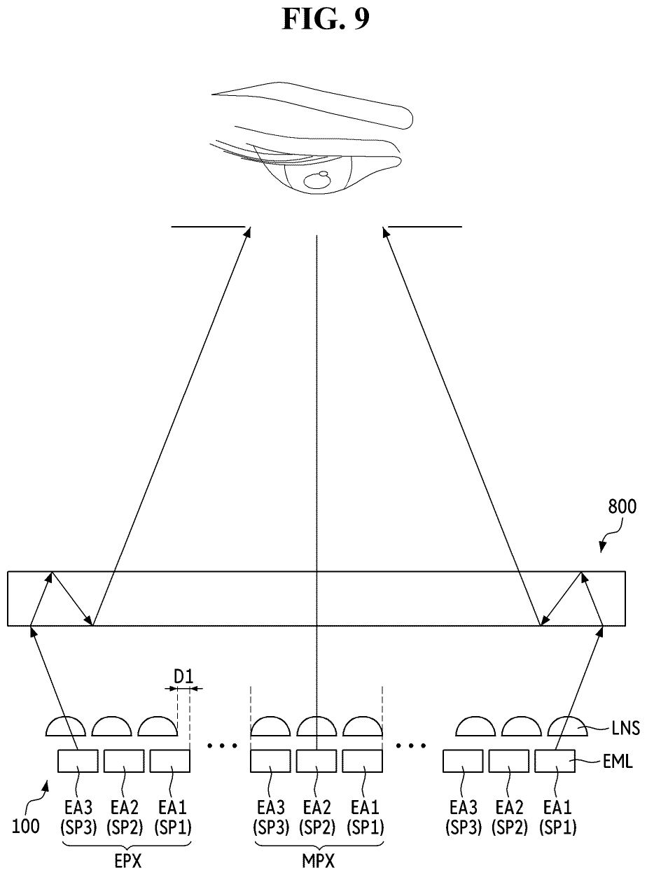

The drawing illustrates that the polarizing plate POL is mounted on the display panel 100, but the present disclosure is not limited thereto. For example, the polarizing plate POL may be included in the optical module 800 (see FIG. 9), which will be described later, and in this case, the polarizing plate POL may have the same component as a first optical module 810 (see FIG. 9) of the optical module 800 (see FIG. 9). That is, the polarizing plate POL may be provided by being mounted on the display panel 100 or may be provided by being mounted on the optical module 800 (see FIG. 9).

FIG. 8 is a cross-sectional view illustrating still another example of a display panel taken along the line I1-I1′ of FIG. 5.

The one or more embodiments corresponding to FIG. 8 differs from the one or more embodiments corresponding to FIG. 7 in that the first electrode AND of each of the light-emitting elements LE is in contact with and electrically connected to the side surface of a connection electrode ANC connected to the eighth conductive layer ML8. The one or more embodiments corresponding to FIG. 8 also differs from the one or more embodiments corresponding to FIG. 7 in that the trench TRC is omitted, and instead, the third pixel-defining film PDL3 and a fourth pixel-defining film PDL4 have an eaves-shaped or mushroom-shaped cross-sectional structure. In the one or more embodiments corresponding to FIG. 8, redundant description of parts already described in the one or more embodiments corresponding to FIG. 7 will be omitted.

Referring to FIG. 8, the plurality of connection electrodes ANC may be respectively located on first portions AA1 of the ninth insulating film INS9. Each of the plurality of connection electrodes ANC may be located on the first portion AA1 of the ninth insulating film INS9 corresponding thereto. A plurality of connection electrodes ANC may include any one of copper (Cu), aluminum (Al), tungsten (W), molybdenum (Mo), chromium (Cr), gold (Au), titanium (Ti), nickel (Ni), or neodymium (Nd), an alloy including any one of them, or a transparent conductive oxide. For example, the plurality of connection electrodes ANC may include titanium (Ti), titanium nitride (TiN), indium tin oxide (ITO), or indium zinc oxide (IZO), but the present disclosure is limited thereto.

A plurality of reflective electrodes RL may be respectively located on the plurality of connection electrodes ANC. Each of the plurality of reflective electrodes RL may be located on the connection electrode ANC corresponding thereto. The plurality of reflective electrodes RL may include any one of copper (Cu), aluminum (Al), tungsten (W), molybdenum (Mo), chromium (Cr), gold (Au), titanium (Ti), nickel (Ni), or neodymium (Nd), or an alloy including any one of them. For example, each of the plurality of reflective electrodes RL may include aluminum (Al) having high reflectivity.

A plurality of optical auxiliary films OAL may be respectively located on the plurality of reflective electrodes RL. Each of the plurality of optical auxiliary films OAL may be located on the reflective electrode RL corresponding thereto. The plurality of optical auxiliary films OAL may be formed as silicon oxide (SiOₓ)-based inorganic films, but the present disclosure is not limited thereto.

In each of the first emission area EA1 and the third emission area EA3, a step layer STPL may be located on the reflective electrode RL, and the optical auxiliary film OAL may be located on the step layer STPL. In the second emission area EA2, only the optical auxiliary film OAL may be located on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary film OAL may be set in consideration of the wavelength and resonance distance of light emitted from the first stack layer IL1 of the light-emitting stack IL, and the wavelength and resonance distance of light emitted from the second stack layer IL2.

Each of the light-emitting elements LE may include the first electrode AND, the light-emitting stack IL, and the second electrode CAT.

The first electrode AND of each of the light-emitting elements LE may be located on the optical auxiliary film OAL corresponding thereto. Because the connection electrode ANC, the reflective electrode RL, and the optical auxiliary film OAL are sequentially stacked, the first electrode AND of each of the light-emitting elements LE may be located on the top surface and the side surface of the optical auxiliary film OAL, the side surface of the reflective electrode RL, and the side surface of the connection electrode ANC. Accordingly, the first electrode AND of each of the light-emitting elements LE may be in contact with and electrically connected to the side surface of the reflective electrode RL and the side surface of the connection electrode ANC. Therefore, compared to when the first electrode AND of each of the light-emitting elements LE is connected to the reflective electrode RL exposed through a through hole penetrating the optical auxiliary film OAL, the number of mask processes may be reduced, thereby advantageously lowering manufacturing cost and increasing manufacturing efficiency.

The first electrode AND of each of the light-emitting elements LE may be connected to the drain region DA or the source region SA of the pixel transistor PTR through the connection electrode ANC, the first to ninth vias VA1 to VA9, the first to eighth conductive layers ML1 to ML8, and the contact terminal CTE.

The ninth insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth insulating film INS9 may be substantially the same.

Alternatively, the thickness of the first portion AA1 of the ninth insulating film INS9 may be greater than the thickness of the second portion AA2. In this case, the side surface of the first portion AA1 of the ninth insulating film INS9 may be exposed, and the first electrode AND of each of the light-emitting elements LE may be located on the exposed side surface of the first portion AA1 of the ninth insulating film INS9.

The first electrode AND of each of the light-emitting elements LE may include any one of copper (Cu), aluminum (Al), tungsten (W), molybdenum (Mo), chromium (Cr), gold (Au), titanium (Ti), nickel (Ni), or neodymium (Nd), an alloy including any one of them, or a transparent conductive oxide. For example, the first electrode AND of each of the light-emitting elements LE may include titanium (Ti), titanium nitride (TiN), indium tin oxide (ITO), or indium zinc oxide (IZO), but the present disclosure is not limited thereto.

The pixel-defining film PDL may be located on a part of the first electrode AND of each of the light-emitting elements LE. The pixel-defining film PDL may cover the edge of the first electrode AND of each of the light-emitting elements LE. The pixel-defining film PDL may partition the first emission areas EA1, the second emission areas EA2, and the third emission areas EA3.

The pixel-defining film PDL may include first to fourth pixel-defining films PDL1, PDL2, PDL3, and PDL4.

The first pixel-defining film PDL1 may be located on the first electrode AND of each of the light-emitting elements LE. For example, the first pixel-defining film PDL1 may cover a part of the top surface of the first electrode AND located on the optical auxiliary film OAL. Further, the first pixel-defining film PDL1 may cover the first electrode AND located on the side surface of the connection electrode ANC, the side surface of the reflective electrode RL, and the side surface of the optical auxiliary film OAL. The first pixel-defining film PDL1 may be located on the top surface of the second portion AA2 of the ninth insulating film INS9.

A planarization film PNS is a film for flattening the stepped portion caused by the connection electrode ANC, the reflective electrode RL, and the optical auxiliary film OAL.

The planarization film PNS may be located on the first pixel-defining film PDL1 covering the first electrode AND located on the side surface of the connection electrode ANC, the side surface of the reflective electrode RL, and the side surface of the optical auxiliary film OAL. The planarization film PNS may be located on the first pixel-defining film PDL1 located on the second portion AA2 of the ninth insulating film INS9.

The planarization film PNS may be located between the connection electrodes ANC adjacent in the first direction DR1 or the second direction DR2. The planarization film PNS may be located between the reflective electrodes RL adjacent in the first direction DR1 or the second direction DR2. The planarization film PNS may be located between the optical auxiliary films OAL adjacent in the first direction DR1 or the second direction DR2.

The step layer STPL is not present in the second emission area EA2, whereas the step layer STPL is present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel-defining film PDL1 located on the top surface of the first electrode AND located in the second emission area EA2.

In contrast, the top surface of the planarization film PNS may be flatly connected to the top surface of the first pixel-defining film PDL1 located on the top surface of the first electrode AND located in the first emission area EA1 and the third emission area EA3. That is, the planarization film PNS may not cover the top surface of the first pixel-defining film PDL1 located on the top surface of the first electrode AND located in each of the first emission area EA1 and the third emission area EA3.

The second pixel-defining film PDL2 may be located on the first pixel-defining film PDL1 and the planarization film PNS, the third pixel-defining film PDL3 may be located on the second pixel-defining film PDL2, and the fourth pixel-defining film PDL4 may be located on the third pixel-defining film PDL3. The first pixel-defining film PDL1 and the third pixel-defining film PDL3 may be formed as silicon nitride (SiNₓ)-based inorganic films, whereas the second pixel-defining film PDL2, the fourth pixel-defining film PDL4, and the planarization film PNS may be formed as silicon oxide (SiOₓ)-based inorganic films. The first pixel-defining film PDL1 includes a material different from that of the planarization film PNS, and thus may serve as a stopper in a chemical mechanical polishing process for the planarization film PNS.

When the planarization film PNS and the second pixel-defining film PDL2 are both formed as silicon oxide (SiOₓ)-based inorganic films, the planarization film PNS and the second pixel-defining film PDL2 may be formed as a single film.

Because the length of the third pixel-defining film PDL3 in one direction is less than the length of the fourth pixel-defining film PDL4 in one direction, the bottom surface of the fourth pixel-defining film PDL4 may be exposed without being covered by the third pixel-defining film PDL3. In other words, the third pixel-defining film PDL3 and the fourth pixel-defining film PDL4 may have an eaves-shaped or mushroom-shaped cross-sectional structure.

The light-emitting stack IL may be located on the first electrode AND and the pixel-defining film PDL. The light-emitting stack IL may include the first stack layer IL1 and the second stack layer IL2 that emit different lights. When the light-emitting stack IL has a two-tandem structure, one of the first stack layer IL1 or the second stack layer IL2 may emit light that includes the wavelength range of any one of the first light, the second light, or the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Here, the first light may be light of a blue wavelength band, the second light may be light of a green wavelength band, and the third light may be light of a red wavelength band.

A charge generation layer for supplying charges to the second stack layer IL2 and for supplying electrons to the first stack layer IL1 may be located between the first stack layer IL1 and the second stack layer IL2. The charge generation layer may include an n-type charge generation layer that supplies electrons to the first stack layer IL1 and a p-type charge generation layer that supplies holes to the second stack layer IL2. The n-type charge generation layer may include a dopant of a metal material.

The first stack layer IL1 is not formed on the bottom surface of the fourth pixel-defining film PDL4 that is exposed without being covered by the third pixel-defining film PDL3, and thus may be cut off by the eaves-shaped or mushroom-shaped cross-sectional structure of the third pixel-defining film PDL3 and the fourth pixel-defining film PDL4. In this case, the first hole transport layer of the first stack layer IL1, and a charge generation layer located between the first stack layer IL1 and the second stack layer IL2 may also be cut off. Further, although FIG. 8 illustrates that the second stack layer IL2 is connected without being cut off, the second hole transport layer of the second stack layer IL2 may be cut off, and the second electron transport layer of the second stack layer IL2 may be connected without being cut off. Therefore, it is possible to reduce or prevent a leakage current flowing through the first hole transport layer of the first stack layer IL1, the second hole transport layer of the second stack layer IL2, and the charge generation layer CGL between the adjacent emission areas EA1, EA2, and EA3. Accordingly, it is possible to reduce or prevent the light-emitting stack IL in the adjacent emission areas EA1, EA2, and EA3 emitting light other than the originally intended light due to the influence of the above current.

Although FIG. 8 illustrates a two-tandem structure in which the light-emitting stack IL includes two stack layers IL1 and IL2, the present disclosure is not limited thereto. For example, the light-emitting stack IL may have a three-tandem structure including three stack layers as shown in FIG. 7. In this case, it may be designed such that the charge generation layer between the first stack layer IL1 and the second stack layer IL2, and the charge generation layer between the second stack layer IL2 and the third stack layer IL3 are cut off by adjusting the height of the third pixel-defining film PDL3. Alternatively, as shown in FIG. 7, the trench TRC penetrating the first pixel-defining film PDL1, the planarization film PNS, the second pixel-defining film PDL2, and the third pixel-defining film PDL3 may be added. In this case, the trench TRC may penetrate at least a part of the ninth insulating film INS9, but the present disclosure is not limited thereto.

Although the one or more embodiments corresponding to FIG. 8 is illustrated as not including the optical layer OPL of FIG. 7, the present disclosure is not limited thereto. The one or more embodiments corresponding to FIG. 8 may also further include the optical layer OPL between the adhesive layer ADL and the cover layer CVL.

FIG. 9 is a schematic cross-sectional view illustrating a display element layer, lenses, and an optical module of a display device according to one or more embodiments.

Referring to FIG. 9 in addition to FIGS. 2 and 7, some of the plurality of lenses LNS may be located in a straight line with each of the emission areas EA1, EA2, and EA3, and some others of the plurality of lenses LNS may be located to be shifted in one direction with respect to each of the emission areas EA1, EA2, and EA3.

For example, the display device 10 may include a middle pixel MPX and an edge pixel EPX. The middle pixel MPX refers to the pixel PX positioned in the middle among the pixels PX, and the edge pixel EPX refers to the pixel PX positioned at the edge among the pixels PX.

The plurality of sub-pixels SP1, SP2, and SP3 included in the middle pixel MPX may be located in parallel with the plurality of lenses LNS located above the sub-pixels SP1, SP2, and SP3, respectively. For example, the plurality of sub-pixels SP1, SP2, and SP3 included in the middle pixel MPX may be respectively located in a straight line in the thickness direction (e.g., the third direction DR3) of the display panel 100 with respect to the plurality of lenses LNS located above the sub-pixels SP1, SP2, and SP3.

The plurality of sub-pixels SP1, SP2, and SP3 included in the edge pixel EPX may be respectively located to be shifted by a first distance D1 with respect to the plurality of lenses LNS located above the sub-pixels SP1, SP2, and SP3. For example, the plurality of sub-pixels SP1, SP2, and SP3 included in the edge pixel EPX may be respectively located to be offset horizontally in the thickness direction (e.g., the third direction DR3) of the display panel 100 with respect to the plurality of lenses LNS located above the sub-pixels SP1, SP2, and SP3.

In the display device 10, the size of the first distance D1 that is the degree to which the plurality of sub-pixels SP1, SP2, and SP3 are shifted with respect to the plurality of lenses LNS may increase in the direction from the middle pixel MPX to the edge pixel EPX. Accordingly, the average luminance amount of the display device 10 may be improved according to the chief ray array (CRA) angle distribution. That is, the overall luminous efficiency of the display device 10 may be improved from various angles.

For example, when light emitted from the plurality of sub-pixels SP1, SP2, and SP3 included in the middle pixel MPX is incident on the optical module 800, the light may be incident generally parallel to a normal line (e.g., the vertical line in the drawing). On the other hand, when light emitted from the plurality of sub-pixels SP1, SP2, and SP3 included in the edge pixel EPX is incident on the optical module 800, the light may be incident generally at a selected angle with respect to the normal line. Accordingly, the shift may be performed by the first distance D1 such that the lens LNS (e.g., approximately the middle of the lens LNS) is located on an extension line extending from the display element layer EML of each of the pixels PX to the incident point of the optical module 800, so that the average luminance amount according to the chief ray array (CRA) angle distribution may be improved.

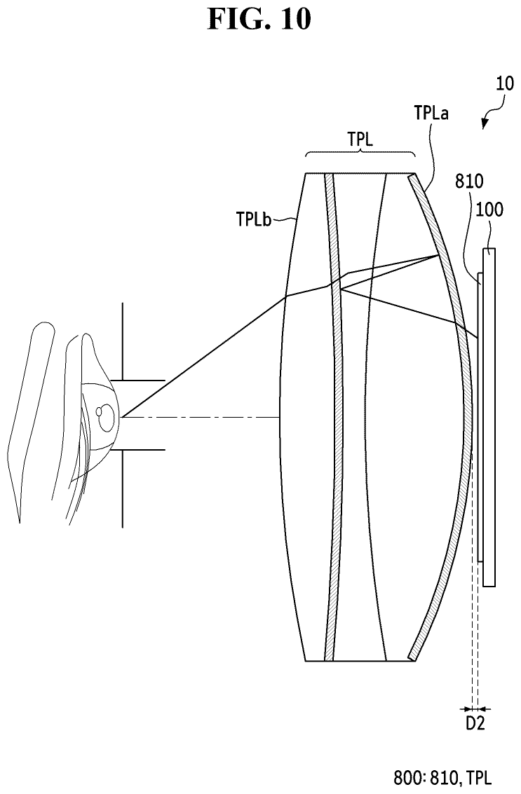

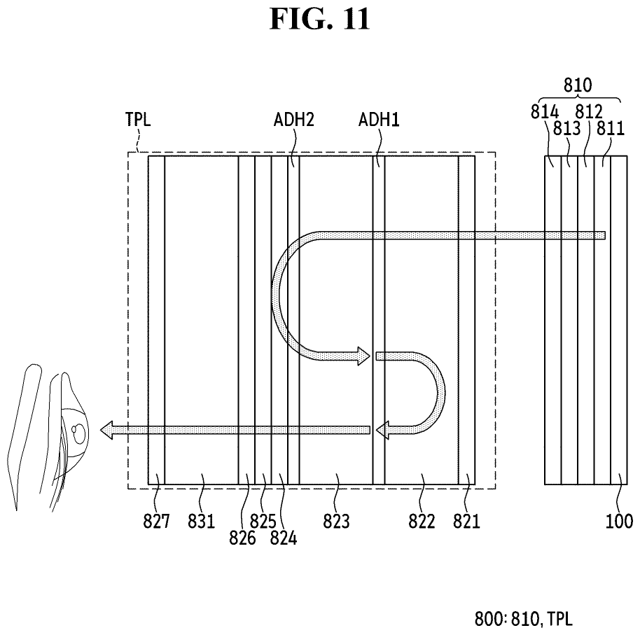

FIGS. 10 and 11 are cross-sectional views showing a display device according to one or more embodiments.

Referring to FIGS. 10 and 11 in addition to FIGS. 7 and 9, the display device 10 may include the display panel 100 and the optical module 800 located on the display panel 100.

Because the display panel 100 has been described with reference to FIG. 7 and the like, description of the display panel 100 will be omitted.

The optical module 800 may include a first optical module 810 and an optical array module TPL. The first optical module 810 may be located on the display panel 100, and the optical array module TPL may be located on the first optical module 810.

In some embodiments, the first optical module 810 may be located directly on the display panel 100. For example, the first optical module 810 may be directly attached to the display panel 100. The optical array module TPL may be spaced apart from the first optical module 810 by a second distance D2. An air gap filled with air may be positioned between the optical array module TPL and the first optical module 810.

The first optical module 810 may include a first phase retardation film 811, a first polarizing film 812, a second phase retardation film 813, and a first coating film 814. The optical array module TPL may include a semi-transmissive reflective film 821, a first lens 822, a first adhesive layer ADH1, a second lens 823, a second adhesive layer ADH2, a third phase retardation film 824 (e.g., a second phase retardation film in the claims), a second polarizing film 825, a third polarizing film 826, a third lens 831, and a second coating film 827.

The first optical module 810 may be the same component as the polarizing plate POL of the display panel 100 described with reference to FIG. 7. The display device 10 may include either the polarizing plate POL of the display panel 100 or the first optical module 810 of the optical module 800.

The first phase retardation film 811 may be located on the display panel 100. For example, the first phase retardation film 811 may be located on the cover layer CVL of the display panel 100. The first phase retardation film 811 may delay the phase of light that has passed through the first phase retardation film 811. When linearly polarized light passes through the first phase retardation film 811, the light may be circularly polarized or elliptically polarized, and when circularly polarized or elliptically polarized light passes through the first phase retardation film 811, the light may be linearly polarized. In one or more embodiments, the first phase retardation film 811 may be a λ/4 plate (quarter-wave plate). In some embodiments, the first phase retardation film 811 may be omitted.

The first polarizing film 812 may be located on the first phase retardation film 811. The first polarizing film 812 may have a first polarization axis extending in one direction. The first polarizing film 812 may be a linear polarizing film. The first polarizing film 812 may linearly polarize light in the direction of the first polarization axis. For example, the first polarizing film 812 may pass light vibrating in a direction parallel to the first polarization axis and may block light vibrating in a direction not parallel to the first polarization axis.

In one or more embodiments, the first polarizing film 812 may be an absorption-type polarizing film. In this case, the first polarizing film 812 may pass light vibrating in a direction parallel to the first polarization axis and may absorb light vibrating in a direction not parallel to the first polarization axis.

The second phase retardation film 813 may be located on the first polarizing film 812. The second phase retardation film 813 may delay the phase of light that has passed through the second phase retardation film 813. When linearly polarized light passes through the second phase retardation film 813, the light may be circularly polarized or elliptically polarized, and when circularly polarized or elliptically polarized light passes through the second phase retardation film 813, the light may be linearly polarized. In one or more embodiments, the second phase retardation film 813 may be a λ/4 plate (quarter-wave plate).

The first coating film 814 may be located on the second phase retardation film 813. The first coating film 814 may be an anti-reflection film. The first coating film 814 may be formed by anti-reflection coating. The first coating film 814 may reduce or prevent reflection of light passing through the top surface (left side in the drawing) of the first optical module 810. Accordingly, the light output efficiency may be improved, and the occurrence of stray light may be reduced or minimized.

The optical array module TPL may be a triplet lens. For example, the optical array module TPL may be a lens in which the first lens 822, the second lens 823, and the third lens 831 are combined. The first adhesive layer ADH1 may be arranged between the first lens 822 and the second lens 823, and the second adhesive layer ADH2 may be arranged between the second lens 823 and the third lens 831. The first lens 822, the second lens 823, and the third lens 831 may be combined with each other by the first adhesive layer ADH1 and the second adhesive layer ADH2.

In some embodiments, the optical array module TPL may include a plastic lens. For example, the optical array module TPL may include a lens containing at least one of polymethylmethacrylate (PMMA)-based plastic, cyclic olefin copolymer (COC)-based plastic, or polycarbonate (PC)-based plastic. In one or more embodiments, the first lens 822 may include at least one of polymethylmethacrylate (PMMA)-based plastic, or cyclic olefin copolymer (COC)-based plastic, the second lens 823 may include polycarbonate (PC)-based plastic, and the third lens 831 may include at least one of polymethylmethacrylate (PMMA)-based plastic or cyclic olefin copolymer (COC)-based plastic.

The display device 10 may reduce the thickness of the optical module 800 by including a triplet lens. Accordingly, it may become easier to ensure the optimal or improved distance for eye relief. Additionally, the field of view (FOV) may be increased through aberration correction and focus correction by using a triplet lens. In addition, because the optical array module TPL includes plastic, processing of the triplet lens and aspherical processing to be described later may be facilitated. Further, because the triplet lens is included, an air gap located between separate lenses spaced apart from each other may be eliminated, and light loss due to reflection at the interface between the air gap and the lens may be reduced or minimized, thereby increasing light efficiency.

In some embodiments, the average curvatures of a first surface TPLa and a second surface TPLb of the optical array module TPL may be different. For example, the average curvature of the first surface TPLa of the optical array module TPL may be greater than the average curvature of the second surface TPLb. In one or more embodiments, the first surface TPLa and the second surface TPLb of the optical array module TPL may be aspherical surfaces including multiple curvatures. The first surface TPLa of the optical array module TPL is a surface facing the first optical module 810, and the second surface TPLb is a surface positioned on the opposite side of the first surface TPLa.

In the display device 10, the optical array module TPL may include an aspherical surface, so that the color crosstalk (or color X-talk) phenomenon may be improved. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and concurrently or substantially simultaneously adjusting each of the plurality of curvatures of the aspherical surface of the optical array module TPL, the average luminance amount according to the chief ray array (CRA) angle distribution may be further improved.

In some embodiments, the refractive index of the second lens 823 may be greater than the refractive indices of the first lens 822 and the third lens 831. Therefore, when the first lens 822, the second lens 823, and the third lens 831 are arranged in that order, the lens with the low refractive index and the lens with the high refractive index may be arranged alternately. Accordingly, the chromatic aberration phenomenon of light having passed through the optical array module TPL may be reduced or minimized.

In some embodiments, the refractive index of each of the first adhesive layer ADH1 and the second adhesive layer ADH2 may be greater than the refractive indices of the first lens 822, the second lens 823, and the third lens 831. In one or more embodiments, the refractive indices of the first adhesive layer ADH1 and the second adhesive layer ADH2 may be about 1.7 or more, and the refractive indices of the first lens 822, the second lens 823, and the third lens 831 may be about less than about 1.7.

In the present disclosure, the refractive index refers to an absolute refractive index measured using sodium D-lines (yellow light with a wavelength λ of approximately 589 nm) at room temperature and humidity (temperature of about 20±15° C., humidity of about 65±20%). For example, in the present specification, the refractive index may be an absolute refractive index measured based on a wavelength of about 589 nm according to Cauchy's model using a refractive index meter (e.g., M-2000 ellipsometer, J. A. Woollam Co., Inc.) under a temperature of about 25° C. and a relative humidity of about 65%.

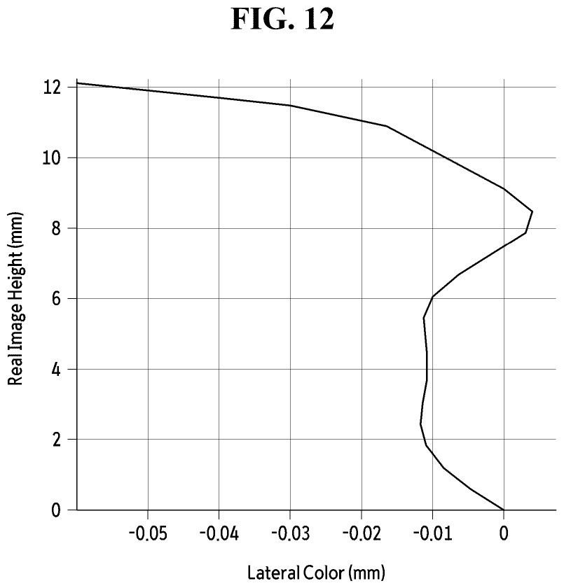

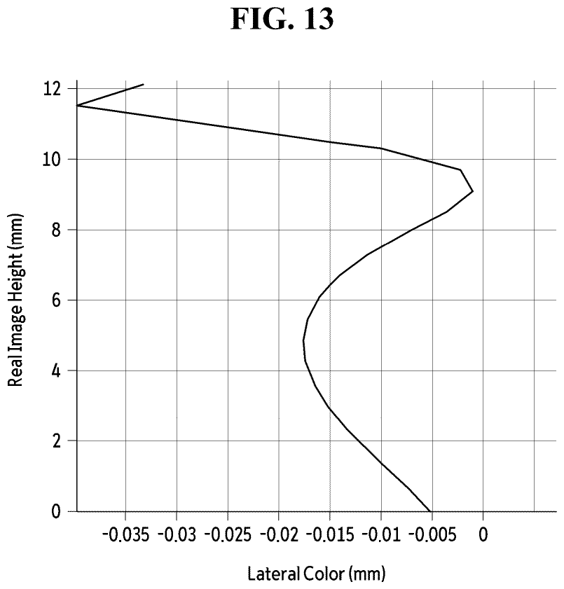

In the display device 10, because the first adhesive layer ADH1 and the second adhesive layer ADH2 have high refractive indices, the layer with the low refractive index and the layer with the high refractive index may be arranged alternately when the first lens 822, the first adhesive layer ADH1, the second lens 823, the second adhesive layer ADH2, and the third lens 831 are arranged in that order. Accordingly, the chromatic aberration phenomenon of light having passed through the optical array module TPL may be reduced or minimized. Details on the improvement of chromatic aberration will be described later with reference to FIGS. 12 and 13.

The semi-transmissive reflective film 821 may be located on the first surface TPLa of the optical array module TPL. For example, the semi-transmissive reflective film 821 may be located on the first lens 822. The semi-transmissive reflective film 821 may be located between the first lens 822 and the first optical module 810. The semi-transmissive reflective film 821 may transmit part of light and may reflect the remaining part. For example, the semi-transmissive reflective film 821 may be a half mirror.

Light transmitted through the semi-transmissive reflective film 821 may be transmitted without phase change. Light reflected from the semi-transmissive reflective film 821 may be reflected with its phase reversed. For example, left-circularly polarized light may be reflected from the semi-transmissive reflective film 821 to be right-circularly polarized light, and the right-circularly polarized light may be reflected from the semi-transmissive reflective film 821 to be left-circularly polarized light.

The semi-transmissive reflective film 821 may be conformally formed according to the shape of the first surface TPLa of the optical array module TPL. Because the first surface TPLa of the optical array module TPL is an aspherical surface including a plurality of curvatures, the viewing angle and the magnification ratio may be increased. Accordingly, the number of components of the optical module 800 may be reduced and the thickness of the display device 10 may be reduced.

The third phase retardation film 824 may be located on the second lens 823. For example, the third phase retardation film 824 may be bonded to the second lens 823 via the second adhesive layer ADH2. The third phase retardation film 824 may delay the phase of light that has passed through the third phase retardation film 824. When linearly polarized light passes through the third phase retardation film 824, the light may be circularly polarized or elliptically polarized, and when circularly polarized or elliptically polarized light passes through the third phase retardation film 824, the light may be linearly polarized. In one or more embodiments, the third phase retardation film 824 may be a λ/4 plate (quarter-wave plate).

The second polarizing film 825 may be located on the third phase retardation film 824. The second polarizing film 825 may have a second polarization axis extending in one direction. The second polarizing film 825 may be a linear polarizing film. The second polarizing film 825 may linearly polarize light in the direction of the second polarization axis. For example, the second polarizing film 825 may pass light vibrating in a direction parallel to the second polarization axis and may block light vibrating in a direction not parallel to the second polarization axis.

In one or more embodiments, the second polarizing film 825 may be a reflective polarizing film. In this case, the second polarizing film 825 may pass light vibrating in a direction parallel to the second polarization axis and may reflect light vibrating in a direction not parallel to the second polarization axis.

The third polarizing film 826 may be located on the second polarizing film 825. The third polarizing film 826 may have a third polarization axis extending in one direction. The third polarizing film 826 may be a linear polarizing film. The third polarizing film 826 may linearly polarize light in the direction of the third polarization axis. For example, the third polarizing film 826 may pass light vibrating in a direction parallel to the third polarization axis and may block light vibrating in a direction not parallel to the third polarization axis. In some embodiments, the third polarizing film 826 may be omitted.

In one or more embodiments, the third polarizing film 826 may be an absorption-type polarizing film. In this case, the third polarizing film 826 may pass light vibrating in a direction parallel to the third polarization axis and may absorb light vibrating in a direction not parallel to the third polarization axis.

The second coating film 827 may be located on the second surface TPLb of the optical array module TPL. For example, the second coating film 827 may be located on the third lens 831. The second coating film 827 may be an anti-reflection film. The second coating film 827 may be formed by anti-reflection coating. The second coating film 827 may reduce or prevent reflection of light passing through the second surface TPLb of the optical array module TPL. Accordingly, the light output efficiency may be improved, and the occurrence of stray light may be reduced or minimized.

In some embodiments, at least one of the first coating film 814 or the second coating film 827 may be omitted depending on the degree of improvement in transmittance and reflectivity of each member.

The first polarization axis of the first polarizing film 812 and the second polarization axis of the second polarizing film 825 may be perpendicular to each other. For example, when the first polarization axis extends in the third direction DR3 that is a perpendicular direction, the second polarization axis may extend in a horizontal direction perpendicular to the third direction DR3.

The second phase retardation film 813 may have a first optical axis. The first optical axis of the second phase retardation film 813 may be tilted by an angle in the range of greater than 0 degrees and less than 90 degrees relative to the first polarization axis of the first polarizing film 812 and/or the second polarization axis of the second polarizing film 825. In one or more embodiments, the first optical axis may be tilted by an angle of approximately 45 degrees relative to the first polarization axis and/or the second polarization axis, but the present disclosure is not limited thereto.

The third phase retardation film 824 may have a second optical axis. The second optical axis of the third phase retardation film 824 may be tilted by an angle in the range of greater than 0 degrees and less than 90 degrees relative to the first polarization axis of the first polarizing film 812 and/or the second polarization axis of the second polarizing film 825. In one or more embodiments, the second optical axis may be tilted by an angle of approximately 45 degrees relative to the first polarization axis and/or the second polarization axis, but the present disclosure is not limited thereto.

The direction in which the first optical axis of the second phase retardation film 813 is tilted with respect to the first polarization axis and/or the second polarization axis may be opposite to the direction in which the second optical axis of the third phase retardation film 824 is tilted with respect to the first polarization axis and/or the second polarization axis. For example, the second phase retardation film 813 may be tilted in the −45 degree direction with respect to the first polarization axis and/or the second polarization axis, and the third phase retardation film 824 may be tilted in the +45 degree direction with respect to the first polarization axis and/or the second polarization axis. Alternatively, the second phase retardation film 813 may be tilted in the +45 degree direction with respect to the first polarization axis and/or the second polarization axis, and the third phase retardation film 824 may be tilted in the −45 degree direction with respect to the first polarization axis and/or the second polarization axis.

The phase retardation direction of light that has passed through the second phase retardation film 813 may be different from the phase retardation direction of light that has passed through the third phase retardation film 824. For example, light that has passed through the second phase retardation film 813 may be delayed by −λ/4, and light that has passed through the third phase retardation film 824 may be delayed by +λ/4.

The display device 10 may implement folded optics that folds the optical path by including the optical module 800. Accordingly, the total track length, which is the total length of the optical path, may be increased while concurrently or substantially simultaneously reducing or minimizing the thickness of the display device 10.

FIG. 12 is a graph showing lateral chromatic aberration and image height of a display device according to a comparative example. FIG. 13 is a graph showing lateral chromatic aberration and image height of a display device according to one or more embodiments.

Referring to FIGS. 12 and 13, the display device 10 according to the comparative example is different from the display device 10 according to one or more embodiments in that it does not include the first adhesive layer ADH1 and the second adhesive layer ADH2.

In the graphs shown in FIGS. 12 and 13, the X-axis represents a lateral chromatic aberration value between the minimum wavelength and the maximum wavelength. The minimum wavelength is approximately 380 nm, and the maximum wavelength is approximately 780 nm. The lateral chromatic aberration value means the degree of chromatic aberration occurring at a side portion (e.g., upper and lower portions of FIG. 10) of the optical module 800. The Y-axis represents a relative height at which an image is formed with respect to an optical axis (e.g., a dashed dotted line extending in a transversal direction of FIG. 10) of the optical module 800.

The maximum chromatic aberration value of the display device 10 according to the comparative example is approximately 0.06 mm, as shown in the graph of FIG. 12, whereas the maximum chromatic aberration value of the display device 10 according to one or more embodiments is approximately 0.04 mm, as shown in the graph of FIG. 13.

In this way, as the display device 10 includes the high-refractive adhesive layer, the chromatic aberration phenomenon of light having passed through the optical array module TPL may be reduced or minimized.

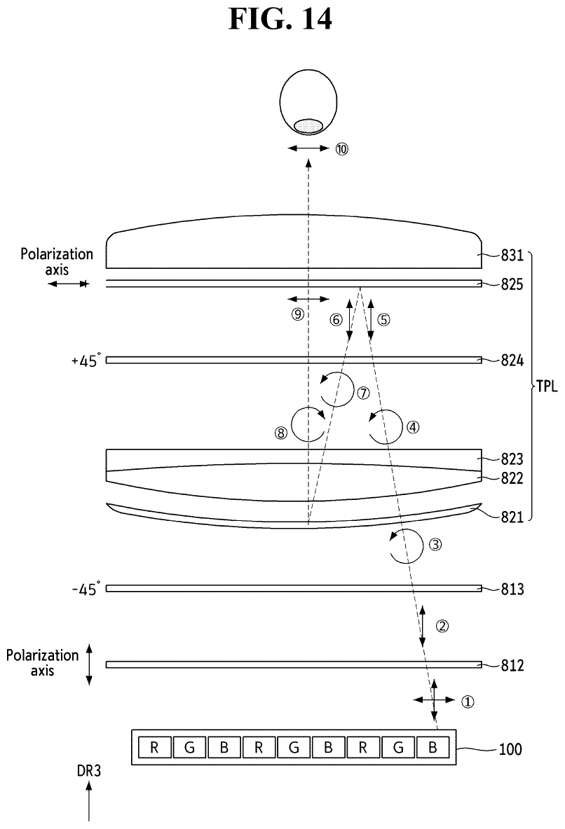

FIG. 14 is a schematic diagram illustrating the path and polarization state of light emitted from a display device according to one or more embodiments. FIG. 14 does not illustrate the first phase retardation film 811 and the third polarizing film 826. Although the first phase retardation film 811 and the third polarizing film 826 are included, the path and polarization state of light emitted from the display device are the same as those described with reference to FIG. 14.

Referring to FIG. 14 in addition to FIGS. 10 and 11, it is illustrated that the first polarization axis of the first polarizing film 812 extends in the perpendicular direction, and the second polarization axis of the second polarizing film 825 extends in the horizontal direction. In addition, it is illustrated that the first polarizing film 812 is an absorption-type polarizing film and the second polarizing film 825 is a reflective polarizing film. In addition, it is illustrated that the first optical axis of the second phase retardation film 813 is tilted by-45 degrees with respect to the perpendicular direction and the second optical axis of the third phase retardation film 824 is tilted by +45 degrees with respect to the perpendicular direction.

Light emitted from the display panel 100 may be unpolarized light \textcircled{1}.

The unpolarized light \textcircled{1} may pass through the first polarizing film 812 with the first polarization axis in the perpendicular direction and may be converted into vertical linear polarized light \textcircled{2} that vibrates in the perpendicular direction.

The vertical linear polarized light \textcircled{2} that has passed through the first polarizing film 812 may pass through the second phase retardation film 813 with the first optical axis tilted by −45 degrees with respect to the perpendicular direction and may be converted into left-circularly polarized light \textcircled{3}.

Part of the left-circularly polarized light \textcircled{3} that has passed through the second phase retardation film 813 may pass through the semi-transmissive reflective film 821. The left-circularly polarized light \textcircled{3} that has passed through the semi-transmissive reflective film 821 may have the same polarization state as the left-circularly polarized light \textcircled{3} that has passed through the second phase retardation film 813 without any change in the polarization state. In one or more embodiments, the remaining part of the left-circularly polarized light \textcircled{3} that has passed through the second phase retardation film 813 may be reflected by the semi-transmissive reflective film 821.

The left-circularly polarized light \textcircled{3} that has passed through the semi-transmissive reflective film 821 may pass through the first lens 822 and the second lens 823, and the image may be magnified. Left-circularly polarized light \textcircled{4} that has passed through the first lens 822 and the second lens 823 may have the same polarization state as the left-circularly polarized light \textcircled{3} that has passed through the semi-transmissive reflective film 821 without any change in the polarization state.

The left-circularly polarized light \textcircled{4} that has passed through the first lens 822 and the second lens 823 may pass through the third phase retardation film 824 with the second optical axis tilted by +45 degrees with respect to the perpendicular direction and may be converted back into vertical linear polarized light \textcircled{5}.

Because the vertical linear polarized light \textcircled{5} that has passed through the third phase retardation film 824 is light polarized in a direction different from the second polarization axis in the horizontal direction, the light may be reflected by the second polarizing film 825. Vertical linear polarized light \textcircled{6} reflected from the second polarizing film 825 may have the same polarization state as the vertical linear polarized light \textcircled{5} that has passed through the third phase retardation film 824 without any change in the polarization state.

The vertical linear polarized light \textcircled{6} reflected from the second polarizing film 825 may pass through the third phase retardation film 824 with the second optical axis tilted by +45 degrees with respect to the perpendicular direction, and may be converted into left-circularly polarized light \textcircled{7}. When the vertical linear polarized light \textcircled{2} that has passed through the first polarizing film 812 passes through the second phase retardation film 813, the light may pass through the second phase retardation film 813, which has the first optical axis tilted by −45 degrees with respect to the perpendicular direction, in the third direction DR3, and thus may be converted into the left-circularly polarized light \textcircled{3}, and on the other hand, the vertical linear polarized light \textcircled{6} reflected from the second polarizing film 825 may pass through the third phase retardation film 824, which has the second optical axis tilted by +45 degrees with respect to the perpendicular direction, in a direction opposite to the third direction DR3, and thus may be converted into the left-circularly polarized light \textcircled{7}.

The left-circularly polarized light \textcircled{7} that has passed through the third phase retardation film 824 may pass through the first lens 822 and the second lens 823, so that the image may be magnified again. The left-circularly polarized light \textcircled{7} that has passed through the first lens 822 and the second lens 823 may have the same polarization state as the left-circularly polarized light \textcircled{7} that has passed through the third phase retardation film 824 without any change in the polarization state.

Part of the left-circularly polarized light \textcircled{7} that has passed through the first lens 822 and the second lens 823 may be reflected by the semi-transmissive reflective film 821, and may be converted into right-circularly polarized light \textcircled{8} by the left and right inversion effect.

The right-circularly polarized light \textcircled{8} reflected from the semi-transmissive reflective film 821 may pass through the first lens 822 and the second lens 823, so that the image may be magnified once more. The right-circularly polarized light \textcircled{8} that has passed through the first lens 822 and the second lens 823 may have the same polarization state as the right-circularly polarized light \textcircled{8} reflected from the semi-transmissive reflective film 821 without any change in the polarization state.

The right-circularly polarized light \textcircled{8} that has passed through the first lens 822 and the second lens 823 may pass through the third phase retardation film 824 with the second optical axis tilted by +45 degrees, and may be converted into horizontal linear polarized light \textcircled{9}.

Because the horizontal linear polarized light \textcircled{9} that has passed through the third phase retardation film 824 is light polarized in the same direction as the second polarization axis in the horizontal direction, the light may pass through the second polarizing film 825. The horizontal linear polarized light \textcircled{9} that has passed through the second polarizing film 825 may have the same polarization state as the horizontal linear polarized light \textcircled{9} that has passed through the third phase retardation film 824 without any change in the polarization state.

The horizontal linear polarized light \textcircled{9} that has passed through the second polarizing film 825 may pass through the third lens 831, and the image may be magnified. Horizontal linear polarized light \textcircled{10} that has passed through the third lens 831 may have the same polarization state as the horizontal linear polarized light \textcircled{9} that has passed through the second polarizing film 825 without any change in the polarization state. The horizontal linear polarized light \textcircled{10} that has passed through the third lens 831 may be provided to the user.

Because the display device 10 includes folded optics, light passes through three lenses a total of seven times, so that the frequency at which the image is magnified increases, and the degree to which the image is magnified may increase because the optical path increases. Accordingly, the thickness of the display device 10 may be reduced, yet a more magnified image may be acquired.

Hereinafter, other embodiments of the display device will be described. In the following embodiments, description of the same components as those described above, which are denoted by like reference numerals, will be omitted or simplified, and differences will be mainly described.

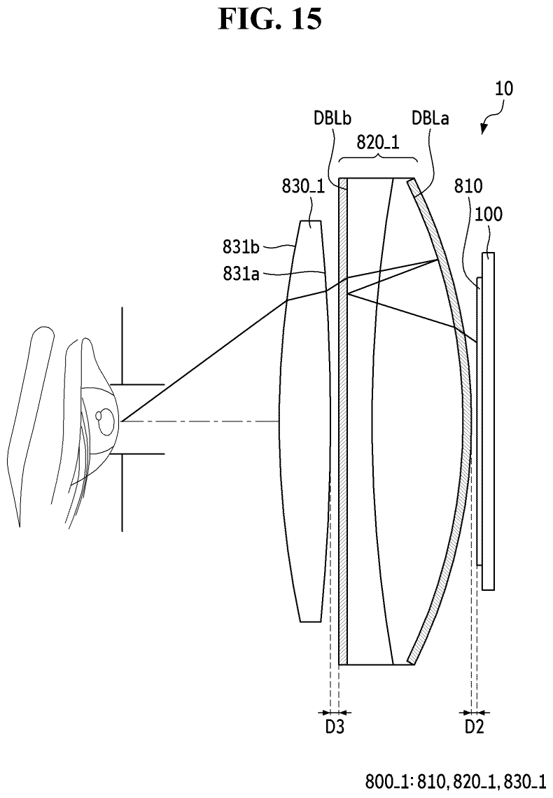

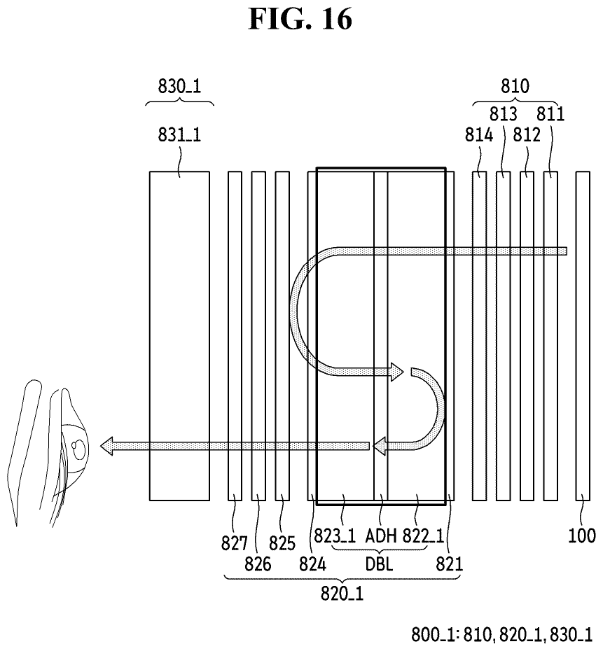

FIGS. 15 and 16 are cross-sectional views showing a display device according to one or more other embodiments.

Referring to FIGS. 15 and 16, the display device 10 of one or more embodiments is different from the display device 10 according to one or more embodiments corresponding to FIG. 10 and the like, in that it includes a doublet lens instead of a triplet lens.

For example, an optical module 800_1 may include a first optical module 810, a second optical module 820_1, and a third optical module 830_1. The first optical module 810 may be located on the display panel 100, the second optical module 820_1 may be located on the first optical module 810, and the third optical module 830_1 may be located on the second optical module 820_1.

In some embodiments, the first optical module 810 may be located directly on the display panel 100. For example, the first optical module 810 may be directly attached to the display panel 100. The second optical module 820_1 may be spaced apart from the first optical module 810 by a second distance D2, and the third optical module 830_1 may be spaced apart from the second optical module 820_1 by a third distance D3. Air gaps filled with air may be positioned between the second optical module 820_1 and the first optical module 810, and between the third optical module 830_1 and the second optical module 820_1, respectively.

The first optical module 810 may include a first phase retardation film 811, a first polarizing film 812, a second phase retardation film 813, and a first coating film 814. The second optical module 820_1 may include a semi-transmissive reflective film 821, a first lens DBL, a third phase retardation film 824, a second polarizing film 825, a third polarizing film 826, and a second coating film 827. The third optical module 830_1 may include a second lens 831_1. The first lens DBL of the second optical module 820_1 may include a first sub-lens 822_1 and a second sub-lens 823_1.

The first optical module 810 may be the same component as the polarizing plate POL of the display panel 100 described with reference to FIG. 7. The display device 10 may include either the polarizing plate POL of the display panel 100 or the first optical module 810 of the optical module 800_1.

The first phase retardation film 811 may be located on the display panel 100. For example, the first phase retardation film 811 may be located on the cover layer CVL of the display panel 100. The first phase retardation film 811 may delay the phase of light that has passed through the first phase retardation film 811. When linearly polarized light passes through the first phase retardation film 811, the light may be circularly polarized or elliptically polarized, and when circularly polarized or elliptically polarized light passes through the first phase retardation film 811, the light may be linearly polarized. In one or more embodiments, the first phase retardation film 811 may be a λ/4 plate (quarter-wave plate). In some embodiments, the first phase retardation film 811 may be omitted.

The first polarizing film 812 may be located on the first phase retardation film 811. The first polarizing film 812 may have a first polarization axis extending in one direction. The first polarizing film 812 may be a linear polarizing film. The first polarizing film 812 may linearly polarize light in the direction of the first polarization axis. For example, the first polarizing film 812 may pass light vibrating in a direction parallel to the first polarization axis, and may block light vibrating in a direction not parallel to the first polarization axis.

In one or more embodiments, the first polarizing film 812 may be an absorption-type polarizing film. In this case, the first polarizing film 812 may pass light vibrating in a direction parallel to the first polarization axis, and may absorb light vibrating in a direction not parallel to the first polarization axis.

The second phase retardation film 813 may be located on the first polarizing film 812. The second phase retardation film 813 may delay the phase of light that has passed through the second phase retardation film 813. When linearly polarized light passes through the second phase retardation film 813, the light may be circularly polarized or elliptically polarized, and when circularly polarized or elliptically polarized light passes through the second phase retardation film 813, the light may be linearly polarized. In one or more embodiments, the second phase retardation film 813 may be a λ/4 plate (quarter-wave plate).

The first coating film 814 may be located on the second phase retardation film 813. The first coating film 814 may be an anti-reflection film. The first coating film 814 may be formed by anti-reflection coating. The first coating film 814 may reduce or prevent reflection of light passing through the top surface (left side in the drawing) of the first optical module 810. Accordingly, the light output efficiency may be improved, and the occurrence of stray light may be reduced or minimized.

The first lens DBL may be located on the first optical module 810. For example, the first lens DBL may be located on the first coating film 814 of the first optical module 810. The first lens DBL may be spaced apart from the first optical module 810. The first lens DBL may magnify an image formed by light generated from the display panel 100.

The first lens DBL may be a doublet lens. For example, the first lens DBL may be a lens in which the first sub-lens 822_1 and the second sub-lens 823_1 are bonded. An adhesive layer ADH may be located between the first sub-lens 822_1 and the second sub-lens 823_1. The first sub-lens 822_1 and the second sub-lens 823_1 may be bonded to each other by the adhesive layer ADH.

In some embodiments, the first lens DBL may include plastic. For example, the first lens DBL may include at least one of polymethylmethacrylate (PMMA)-based plastic, cyclic olefin copolymer (COC)-based plastic, or polycarbonate (PC)-based plastic. The first sub-lens 822_1 and the second sub-lens 823_1 may include different materials. For example, the first sub-lens 822_1 may include at least one of polymethylmethacrylate (PMMA)-based plastic or cyclic olefin copolymer (COC)-based plastic, or the second sub-lens 823_1 may include polycarbonate (PC)-based plastic.

The display device 10 may reduce the thickness of the optical module 800_1 by including a doublet lens. Accordingly, it may become easier to ensure the optimal or improved distance for eye relief. Additionally, the field of view (FOV) may be increased through aberration correction and focus correction by using a doublet lens. Additionally, because the first lens DBL includes plastic, processing of the doublet lens and aspherical surface processing may be facilitated. In addition, because the doublet lens is included, an air gap located between separate lenses spaced apart from each other may be eliminated, and light loss due to reflection at the interface between the air gap and the lens may be reduced or minimized, thereby increasing light efficiency.

In some embodiments, the average curvatures of a first surface DBLa and a second surface DBLb of the first lens DBL may be different. For example, the average curvature of the first surface DBLa of the first lens DBL may be greater than the average curvature of the second surface DBLb. In one or more embodiments, the first surface DBLa of the first lens DBL may be an aspherical surface including a plurality of curvatures, and the second surface DBLb may be a flat surface, but the present disclosure is not limited thereto. The first surface DBLa of the first lens DBL is a surface facing the first optical module 810, and the second surface DBLb is a surface facing the third optical module 830_1.

In the display device 10, the first lens DBL may include an aspherical surface, so that the color crosstalk (or color X-talk) phenomenon may be improved. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX, and concurrently or substantially simultaneously adjusting each of the plurality of curvatures of the aspherical surface of the first lens DBL, the average luminance amount according to the chief ray array (CRA) angle distribution may be further improved.

The semi-transmissive reflective film 821 may be located on the first surface DBLa of the first lens DBL. The semi-transmissive reflective film 821 may be located between the first lens DBL and the first optical module 810. The semi-transmissive reflective film 821 may transmit part of light and reflect the remaining part. For example, the semi-transmissive reflective film 821 may be a half mirror.

Light transmitted through the semi-transmissive reflective film 821 may be transmitted without phase change. Light reflected from the semi-transmissive reflective film 821 may be reflected with its phase reversed. For example, left-circularly polarized light may be reflected from the semi-transmissive reflective film 821 to be right-circularly polarized light, and the right-circularly polarized light may be reflected from the semi-transmissive reflective film 821 to be left-circularly polarized light.

The semi-transmissive reflective film 821 may be conformally formed according to the shape of the first surface DBLa of the first lens DBL. Because the first surface DBLa of the first lens DBL is an aspherical surface including a plurality of curvatures, the viewing angle and the magnification ratio may be increased. Accordingly, the number of components of the optical module 800_1 may be reduced and the thickness of the display device 10 may be reduced.

The third phase retardation film 824 may be located on the second surface DBLb of the first lens DBL. The third phase retardation film 824 may delay the phase of light that has passed through the third phase retardation film 824. When linearly polarized light passes through the third phase retardation film 824, the light may be circularly polarized or elliptically polarized, and when circularly polarized or elliptically polarized light passes through the third phase retardation film 824, the light may be linearly polarized. In one or more embodiments, the third phase retardation film 824 may be a λ/4 plate (quarter-wave plate).

The second polarizing film 825 may be located on the third phase retardation film 824. The second polarizing film 825 may have a second polarization axis extending in one direction. The second polarizing film 825 may be a linear polarizing film. The second polarizing film 825 may linearly polarize light in the direction of the second polarization axis. For example, the second polarizing film 825 may pass light vibrating in a direction parallel to the second polarization axis and may block light vibrating in a direction not parallel to the second polarization axis.

In one or more embodiments, the second polarizing film 825 may be a reflective polarizing film. In this case, the second polarizing film 825 may pass light vibrating in a direction parallel to the second polarization axis, and may reflect light vibrating in a direction not parallel to the second polarization axis.

The third polarizing film 826 may be located on the second polarizing film 825. The third polarizing film 826 may have a third polarization axis extending in one direction. The third polarizing film 826 may be a linear polarizing film. The third polarizing film 826 may linearly polarize light in the direction of the third polarization axis. For example, the third polarizing film 826 may pass light vibrating in a direction parallel to the third polarization axis, and may block light vibrating in a direction not parallel to the third polarization axis. In some embodiments, the third polarizing film 826 may be omitted.

In one or more embodiments, the third polarizing film 826 may be an absorption-type polarizing film. In this case, the third polarizing film 826 may pass light vibrating in a direction parallel to the third polarization axis, and may absorb light vibrating in a direction not parallel to the third polarization axis.

The second coating film 827 may be located on the third polarizing film 826. The second coating film 827 may be an anti-reflection film. The second coating film 827 may be formed by anti-reflection coating. The second coating film 827 may reduce or prevent reflection of light passing through the second surface DBLb of the first lens DBL. Accordingly, the light output efficiency may be improved, and the occurrence of stray light may be reduced or minimized.

The second lens 831_1 may be located on the second optical module 820_1. For example, the second lens 831_1 may be located on the second coating film 827 of the second optical module 820_1. The second lens 831_1 may be spaced apart from the second optical module 820_1. The second lens 831_1 may magnify an image formed by light generated from the display panel 100.

The second lens 831_1 may be a single lens. Lenses of various shapes, such as a convex lens, a meniscus lens, and a Fresnel lens, may be used as the second lens 831_1, and the shape of the second lens 831_1 is not limited.

In some embodiments, the second lens 831_1 may include plastic. For example, the second lens 831_1 may include at least one of polymethylmethacrylate (PMMA)-based plastic or cyclic olefin copolymer (COC)-based plastic.

In some embodiments, the average curvatures of a first surface 831a and a second surface 831b of the second lens 831_1 may be different. For example, the average curvature of the first surface 831a of the second lens 831_1 may be less than the average curvature of the second surface 831b. In one or more embodiments, the first surface 831a and the second surface 831b of the second lens 831_1 may be aspherical surfaces including a plurality of curvatures. The first surface 831a of the second lens 831_1 is a surface facing the second optical module 820_1, and the second surface 831b is a surface positioned on the opposite side of the first surface 831a.

In the display device 10, the second lens 831_1 may include an aspherical surface, so that the color crosstalk (or color X-talk) phenomenon may be improved. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX and concurrently or substantially simultaneously adjusting each of the plurality of curvatures of the aspherical surface of the second lens 831_1, the average luminance amount according to the chief ray array (CRA) angle distribution may be further improved.

In one or more embodiments, a third coating film may be further located on the second surface 831b of the second lens 831_1. The third coating film may be an anti-reflection film. The third coating film may be formed by anti-reflection coating. The third coating film may reduce or prevent reflection of passing through the top surface (left side in the drawing) of the third optical module 830_1 from being reflected. Accordingly, the light output efficiency may be improved, and the occurrence of stray light may be reduced or minimized.

In some embodiments, at least one of the first coating film 814, the second coating film 827, or the third coating film may be omitted depending on the degree of improvement in transmittance and reflectivity of each member.

In some embodiments, the refractive index of the second sub-lens 823_1 may be greater than the refractive indices of the first sub-lens 822_1 and the second lens 831_1. Therefore, when the first sub-lens 822_1, the second sub-lens 823_1, and the second lens 831_1 are arranged in that order, the lens with the low refractive index and the lens with the high refractive index may be arranged alternately. Accordingly, the chromatic aberration phenomenon of light having passed through the first lens DBL and the second lens 831_1 may be reduced or minimized.

In some embodiments, the refractive index of the adhesive layer ADH may be greater than the refractive indices of the first sub-lens 822_1 and the second sub-lens 823_1. In one or more embodiments, the refractive index of the adhesive layer ADH may be approximately 1.7 or more, and the refractive indices of the first sub-lens 822_1 and the second sub-lens 823_1 may be approximately less than about 1.7.

In the display device 10, because the adhesive layer ADH has the high refractive index, the layer with the low refractive index and the layer with the high refractive index may be arranged alternately when the first sub-lens 822_1, the adhesive layer ADH, and the second sub-lens 823_1 are arranged in that order. Accordingly, the chromatic aberration phenomenon of light having passed through the first lens DBL may be reduced or minimized.

The first polarization axis of the first polarizing film 812 and the second polarization axis of the second polarizing film 825 may be perpendicular to each other. For example, when the first polarization axis extends in the third direction DR3 that is a perpendicular direction, the second polarization axis may extend in a horizontal direction perpendicular to the third direction DR3.

The second phase retardation film 813 may have a first optical axis. The first optical axis of the second phase retardation film 813 may be tilted by an angle in the range of greater than 0 degrees and less than 90 degrees relative to the first polarization axis of the first polarizing film 812 and/or the second polarization axis of the second polarizing film 825. In one or more embodiments, the first optical axis may be tilted by an angle of approximately 45 degrees relative to the first polarization axis and/or the second polarization axis, but the present disclosure is not limited thereto.

The third phase retardation film 824 may have a second optical axis. The second optical axis of the third phase retardation film 824 may be tilted by an angle in the range of greater than 0 degrees and less than 90 degrees relative to the first polarization axis of the first polarizing film 812 and/or the second polarization axis of the second polarizing film 825. In one or more embodiments, the second optical axis may be tilted by an angle of approximately 45 degrees relative to the first polarization axis and/or the second polarization axis, but the present disclosure is not limited thereto.

The direction in which the first optical axis of the second phase retardation film 813 is tilted with respect to the first polarization axis and/or the second polarization axis may be opposite to the direction in which the second optical axis of the third phase retardation film 824 is tilted with respect to the first polarization axis and/or the second polarization axis. For example, the second phase retardation film 813 may be tilted in the-45 degree direction with respect to the first polarization axis and/or the second polarization axis, and the third phase retardation film 824 may be tilted in the +45 degree direction with respect to the first polarization axis and/or the second polarization axis. Alternatively, the second phase retardation film 813 may be tilted in the +45 degree direction with respect to the first polarization axis and/or the second polarization axis, and the third phase retardation film 824 may be tilted in the −45 degree direction with respect to the first polarization axis and/or the second polarization axis.

The phase retardation direction of light that has passed through the second phase retardation film 813 may be different from the phase retardation direction of light that has passed through the third phase retardation film 824. For example, light that has passed through the second phase retardation film 813 may be delayed by −λ/4, and light that has passed through the third phase retardation film 824 may be delayed by +λ/4.

The display device 10 may implement folded optics that folds the optical path by including the optical module 800_1. Accordingly, the total track length, which is the total length of the optical path, may be increased while concurrently or substantially simultaneously reducing or minimizing the thickness of the display device 10.

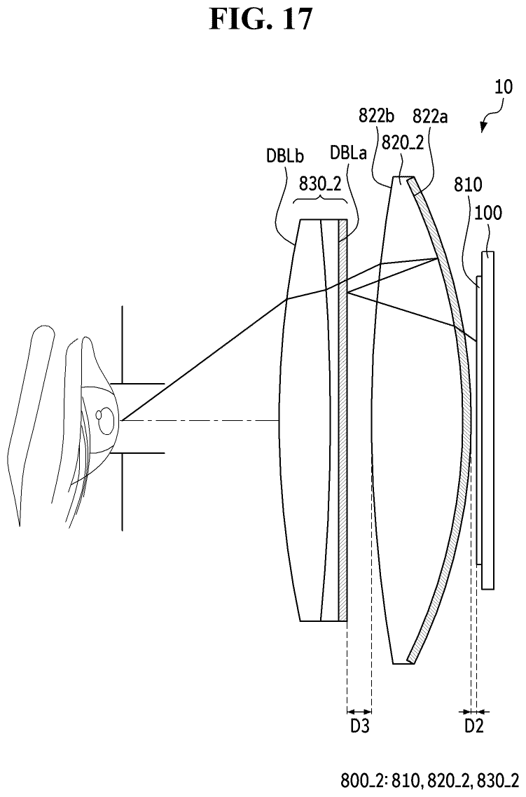

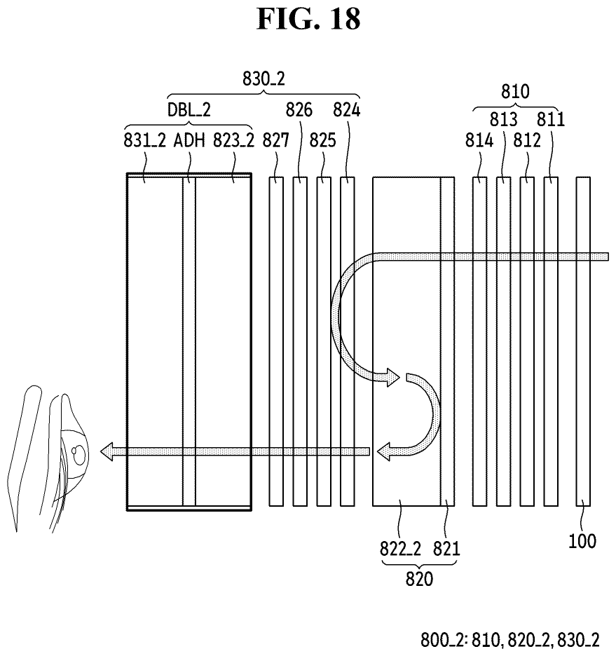

FIGS. 17 and 18 are cross-sectional views showing a display device according to one or more other embodiments.

Referring to FIGS. 17 and 18, the display device 10 according to one or more embodiments is different from the display device 10 according to one or more other embodiments described with reference to FIG. 15 and the like in that the third optical module 830_2 includes a doublet lens.

For example, the first optical module 810 may include the first phase retardation film 811, the first polarizing film 812, the second phase retardation film 813, and the first coating film 814. The second optical module 820_2 may include the semi-transmissive reflective film 821 and a first lens 822_2. The third optical module 830_2 may include the third phase retardation film 824, the second polarizing film 825, the third polarizing film 826, the second coating film 827, and a second lens DBL_2. The second lens DBL_2 of the third optical module 830_2 may include a first sub-lens 831_2 and a second sub-lens 823_2.

The description of the first phase retardation film 811, the first polarizing film 812, the second phase retardation film 813, and the first coating film 814 of the first optical module 810 and the semi-transmissive reflective film 821 of the second optical module 820_2 is the same as the description of each component of the display device 10 according one or more other embodiments described with reference to FIG. 15 and the like, and thus will be omitted. In addition, the descriptions of the third phase retardation film 824, the second polarizing film 825, the third polarizing film 826, and the second coating film 827 of the third optical module 830_2 are respectively the same as the descriptions of the third phase retardation film 824, the second polarizing film 825, the third polarizing film 826, and the second coating film 827 of the display device 10 according to one or more other embodiments described with reference to FIG. 15 and the like, and thus will be omitted.

The first lens 822_2 may be located on the first optical module 810. For example, the first lens 822_2 may be located on the first coating film 814 of the first optical module 810. The first lens 822_2 may be spaced apart from the first optical module 810. The first lens 822_2 may magnify an image formed by light generated from the display panel 100.

The first lens 822_2 may be a single lens. Lenses of various shapes, such as a convex lens, a meniscus lens, and a Fresnel lens, may be used as the first lens 822_2, and the shape of the first lens 822_2 is not limited.

In some embodiments, the first lens 822_2 may include plastic. For example, the first lens 822_2 may include at least one of polymethylmethacrylate (PMMA)-based plastic or cyclic olefin copolymer (COC)-based plastic.

In some embodiments, the average curvatures of a first surface 822a and a second surface 822b of the first lens 822_2 may be different. For example, the average curvature of the first surface 822a of the first lens 822_2 may be greater than the average curvature of the second surface 822b. In one or more embodiments, the first surface 822a and the second surface 822b of the first lens 822_2 may be aspherical surfaces including a plurality of curvatures. The first surface 822a of the first lens 822_2 is a surface facing the first optical module 810, and the second surface 822b is a surface facing the third optical module 830_2.

In the display device 10, the first lens 822_2 may include an aspherical surface, so that the color crosstalk (or color X-talk) phenomenon may be improved. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX, and concurrently or substantially simultaneously adjusting each of the plurality of curvatures of the aspherical surface of the first lens 822_2, the average luminance amount according to the chief ray array (CRA) angle distribution may be further improved.

The second lens DBL_2 may be located on the second coating film 827. The second lens DBL_2 may be spaced apart from the second optical module 820_2. The second lens DBL_2 may magnify an image formed by light generated from the display panel 100.

The second lens DBL_2 may be a doublet lens. For example, the second lens DBL_2 may be a lens in which the first sub-lens 831_2 and the second sub-lens 823_2 are bonded. The adhesive layer ADH may be located between the first sub-lens 831_2 and the second sub-lens 823_2. The first sub-lens 831_2 and the second sub-lens 823_2 may be bonded to each other by the adhesive layer ADH.

In some embodiments, the second lens DBL_2 may include plastic. For example, the second lens DBL_2 may include at least one of polymethylmethacrylate (PMMA)-based plastic, cyclic olefin copolymer (COC)-based plastic, or polycarbonate (PC)-based plastic. The first sub-lens 831_2 and the second sub-lens 823_2 may include different materials. For example, the first sub-lens 831_2 may include at least one of polymethylmethacrylate (PMMA)-based plastic or cyclic olefin copolymer (COC)-based plastic, and the second sub-lens 823_2 may include polycarbonate (PC)-based plastic.

The display device 10 may reduce the thickness of the optical module 800_2 by including a doublet lens. Accordingly, it may become easier to ensure the optimal or improved distance for eye relief. Additionally, the field of view (FOV) may be increased through aberration correction and focus correction by using a doublet lens. Additionally, because the second lens DBL_2 includes plastic, processing of the doublet lens and aspherical surface processing may be facilitated. In addition, because the doublet lens is included, an air gap located between separate lenses spaced apart from each other may be eliminated, and light loss due to reflection at the interface between the air gap and the lens may be reduced or minimized, thereby increasing light efficiency.

In some embodiments, the average curvatures of the first surface DBLa and the second surface DBLb of the second lens DBL_2 may be different. For example, the average curvature of the first surface DBLa of the second lens DBL_2 may be less than the average curvature of the second surface DBLb. In one or more embodiments, the first surface DBLa of the second lens DBL_2 may be a flat surface, and the second surface DBLb may be an aspherical surface including a plurality of curvatures, but the present disclosure is not limited thereto. The first surface DBLa of the second lens DBL_2 is a surface facing the second optical module 820_2, and the second surface DBLb is a surface positioned on the opposite side of the first surface DBLa.

In the display device 10, the second lens DBL_2 may include an aspherical surface, so that the color crosstalk (or color X-talk) phenomenon may be improved. In addition, as described above with reference to FIG. 9, by adjusting the first distance D1 that is the degree to which the plurality of sub-pixels SP1, SP2, and SP3 are shifted with respect to the plurality of lenses LNS in the direction from the middle pixel MPX to the edge pixel EPX, and concurrently or substantially simultaneously adjusting each of the plurality of curvatures of the aspherical surface of the second lens DBL_2, the average luminance amount according to the chief ray array (CRA) angle distribution may be further improved.

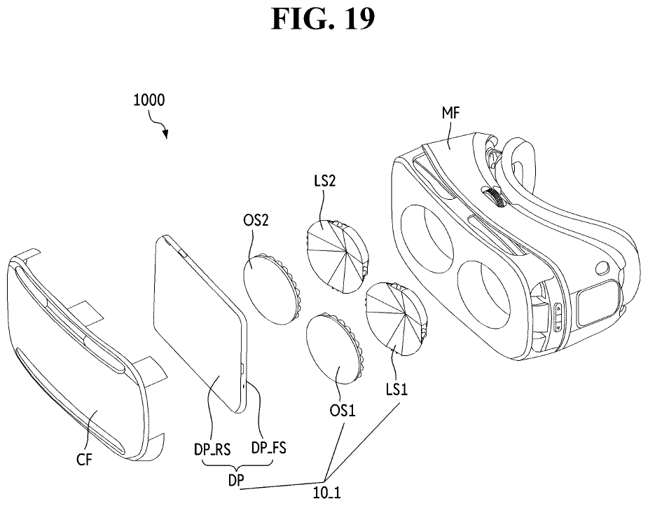

FIG. 19 is an exploded perspective view illustrating a head-mounted display according to one or more embodiments.

Referring to FIG. 19, a head-mounted display 1000 is formed in the form of glasses or a head mount to provide an image to a user using a display device 10_1.

The head-mounted display 1000 may include a see-through type that provides augmented reality based on actual external objects and a see-closed type that provides virtual reality to the user on a screen independent from the external objects.

The head-mounted display 1000 may include a main frame MF mounted on the user's body, the display device 10_1 mounted on the main frame MF to display an image, and a cover frame CF that covers the display device 10_1.

The display device 10_1 may be formed integrally with the head-mounted display 1000 that may be carried by the user and suitably attached to or detached from a face or a head, and may be formed to be assembled to the head-mounted display 1000. The display device 10_1 may be substantially the same as the display device 10 described in conjunction with FIG. 1 and the like.

The display device 10_1 may include a display panel DP that displays an image, first and second lens frames OS1 and OS2 that refract an image display light, and first and second multi-channel lenses LS1 and LS2 that form an optical path so that the image display light of the display panel DP is visible to the user.

The main frame MF may be worn on the user's face and head. The main frame MF may be formed in a shape corresponding to the user's head and facial structure.

The main frame MF may be integrally formed with display device 10_1, that is, the display panel DP, the first and second lens frames OS1 and OS2, and the first and second multi-channel lenses LS1 and LS2. Alternatively, the display panel DP, the first and second lens frames OS1 and OS2, and the first and second multi-channel lenses LS1 and LS2 may be assembled and mounted to the main frame MF. To this end, the main frame MF may have a space or a structure for accommodating the display panel DP, the first and second lens frames OS1 and OS2, and the first and second multi-channel lenses LS1 and LS2. The main frame MF may further include a structure, such as a strap or a band to facilitate the mounting, and a controller, an image processing unit, and a lens accommodating unit may be further included in the main frame MF.

The display panel DP may be divided into a front surface DP_FS where an image is displayed, and a rear surface DP_RS positioned on the opposite side of the front surface DP_FS. Image display light may be emitted from the front surface DP_FS of the display panel DP. As will be described later, the first and second lens frames OS1 and OS2 may be located on the front surface DP_FS of the display panel DP, and the first and second multi-channel lenses LS1 and LS2 may be located on the front surfaces of the first and second lens frames OS1 and OS2. In one or more embodiments, at least one infrared camera may be located on at least one of the front surface DP_FS or the rear surface DP_RS of the display panel DP. The display panel DP may be substantially the same as the display panel 100 described in conjunction with FIG. 1 and the like.

The display panel DP may be built in the main frame MF in a state where the first and second lens frames OS1 and OS2 and the first and second multi-channel lenses LS1 and LS2 are mounted and fixed, or may be detachably assembled to the main frame MF. The display panel DP may be opaque, transparent, or translucent depending on the design of the display device 10_1, for example, the usage type of the display device 10_1.

Each of the first and second lens frames OS1 and OS2 may have an area corresponding to the image display surface of the display panel DP, and may be formed in a shape corresponding to that of the image display surface. Further, the first and second lens frames OS1 and OS2 may be formed to have an area and a shape corresponding to those of the rear surfaces of the first and second multi-channel lenses LS1 and LS2, respectively. The rear surfaces of the first and second lens frames OS1 and OS2 may be attached to the image display surface of the display panel DP, and the first and second multi-channel lenses LS1 and LS2 may be attached to the front surfaces of the first and second lens frames OS1 and OS2, respectively. The first and second lens frames OS1 and OS2 refract the image display light emitted from the image display surface of the display panel DP at a preset angle and provide it to the first and second multi-channel lenses LS1 and LS2 located on the front surfaces thereof, respectively.

For example, the first and second lens frames OS1 and OS2 may refract the image display light, which is emitted from the image display surface of the display panel DP toward the front side, toward an outer side (or toward an outer peripheral side) compared to the front side and provide it to the first and second multi-channel lenses LS1 and LS2 located on the front surfaces thereof, respectively. For example, the first and second lens frames OS1 and OS2 may refract the image display light incident on the rear surfaces thereof toward the outer side (or toward the outer peripheral side), and may provide it to the rear surfaces of the first and second multi-channel lenses LS1 and LS2, respectively.

The first and second multi-channel lenses LS1 and LS2 may form a path for light emitted through the first and second lens frames OS1 and OS2, so that the image display light is visible to the user's eyes on the front side.

The first and second multi-channel lenses LS1 and LS2 may provide a plurality of channels (or paths) through which the image display light emitted from the display panel DP passes. The plurality of channels may provide the image display light emitted from the display panel DP to the user through different paths. The image display light emitted through the first and second lens frames OS1 and OS2 may be incident on the respective channels, and the image magnified through the respective channels may be focused on the user's eyes.

The first and second multi-channel lenses LS1 and LS2 may be respectively arranged on the front surfaces the first and second lens frames OS1 and OS2 to correspond to the positions of the user's left eye and right eye. The first and second multi-channel lenses LS1 and LS2 may be accommodated in the main frame MF.

The first and second multi-channel lenses LS1 and LS2 may refract and/or reflect the image display light emitted through the first and second lens frames OS1 and OS2 at least once to form a path to the user's eyes. At least one infrared light source may be further located at the main frame MF, or on one side of each of the first and second multi-channel lenses LS1 and LS2 facing the user's eyes.

The cover frame CF may be located on the rear surface DP_RS of the display panel DP to cover the display panel DP, and may protect the display panel DP. The cover frame CF may be attached to the main frame MF while covering the display panel DP.

In one or more embodiments, the display device 10_1 may further include a controller for controlling the overall operation of the display device 10_1 including the display panel DP. The controller may control the image display operation of the display panel DP and audio devices. For example, the controller performs image processing (e.g., image mapping) according to the magnification ratio and the image display path corresponding to the first and second lens frames OS1 and OS2 and the first and second multi-channel lenses LS1 and LS2, and controls the mapped image to be displayed on the display panel DP. The controller may be implemented as a dedicated processor including an embedded processor and/or a general-purpose processor including a central processing unit or an application processor, but is not limited thereto.

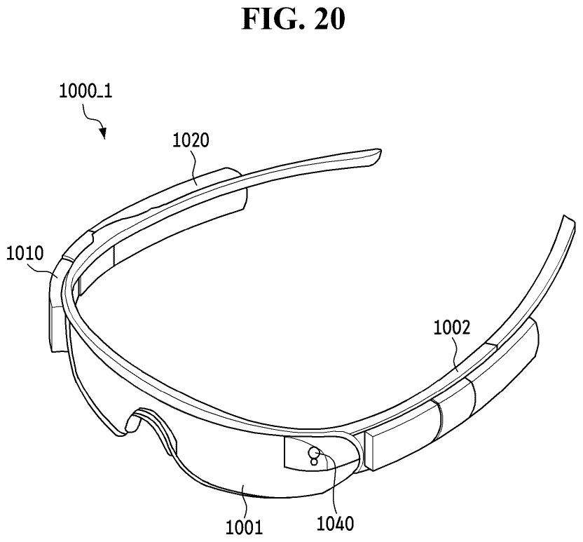

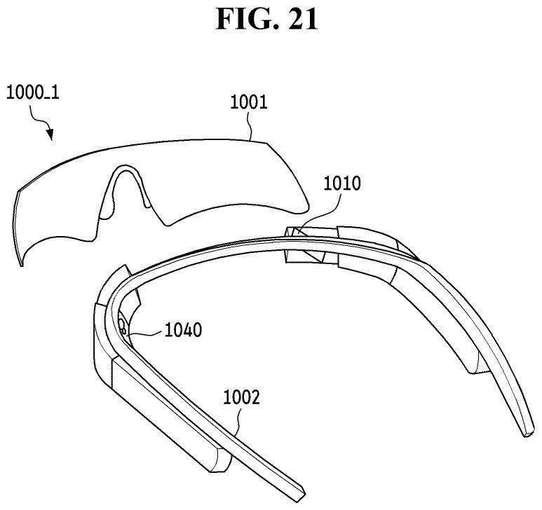

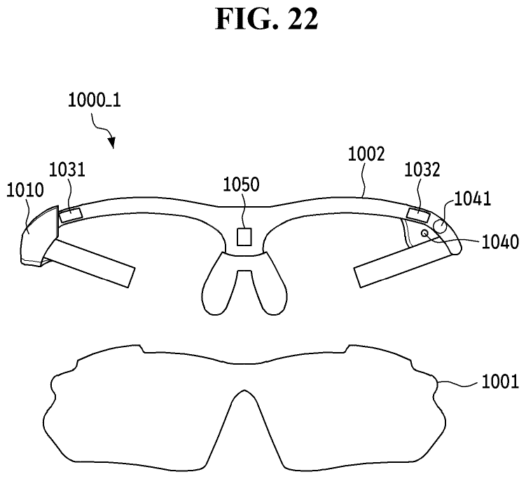

FIG. 20 is a perspective view showing an augmented reality content providing device according to one or more embodiments. FIG. 21 is a rear exploded perspective view of the augmented reality content providing device of FIG. 20. FIG. 22 is a front exploded perspective view of the augmented reality content providing device of FIG. 20.

Referring to FIGS. 20 to 22, an augmented reality content providing device 1000_1 may include a support frame 1002 supporting at least one transparent lens 1001, at least one image display module 1010, a surrounding environment detector 1040, and a control module 1020.

The support frame 1002 may be formed in the form of glasses including a spectacle frame supporting the edge of at least one transparent lens 1001 and spectacle frame legs. The shape of the support frame 1002 is not limited to a glasses type, and may be formed in a goggle type including the transparent lens 1001, or a head-mounted type.

The transparent lens 1001 may include left and right parts formed integrally, or first and second transparent lenses formed separately. The transparent lens 1001, which includes the integrated left and right parts or the separated first and second transparent lenses, may include glass or plastic that is transparent or translucent. Accordingly, the user can view the image of reality through the transparent lens 1001 that includes the integrated right and left parts or the separated first and second transparent lenses. Here, the transparent lens 1001, that is, the integrated lens or the first and second transparent lenses, may have a refractive power in consideration of the user's eyesight.

The transparent lens 1001 may further include at least one reflective member that reflects the augmented reality content image provided from the at least one image display module 1010 toward the transparent lens 1001 or the user's eyes, and optical members that adjust a focus and a size. One or more reflective member may be built in the transparent lens 1001 to be integrated with the transparent lens 1001, and may be formed as a plurality of refractive lenses or a plurality of prisms with a selected curvature.

The at least one image display module 1010 may include a micro LED display device (micro-LED), a nano LED display device (nano-LED), an organic light-emitting display device (OLED), an inorganic light-emitting display device (inorganic EL), a quantum dot light-emitting display device (QED), a cathode ray display (CRT), a liquid crystal display (LCD), or the like. The image display module 1010 may substantially include the display device 10 described with reference to FIG. 1 and the like.

The surrounding environment detector 1040 is assembled or integrally formed with the support frame 1002, and detects the distance (or depth) to an object on the front side of the support frame 1002, the illuminance, the moving direction of the support frame 1002, the moving distance, the tilt, or the like. To this end, the surrounding environment detector 1040 includes a depth sensor 1041, such as an infrared sensor or a LiDAR sensor, and an image sensor 1050, such as a camera. Further, the surrounding environment detector 1040 may further include at least one motion sensor among an illumination sensor, a human body detection sensor, a gyro sensor, a tilt sensor, and an acceleration sensor. Further, the surrounding environment detector 1040 may further include first and second biometric sensors 1031 and 1032 for detecting movement information of the user's eyes or pupils.

The surrounding environment detector 1040 may transmit sensing signals generated by the depth sensor 1041 and at least one motion sensor to the control module 1020 in real time. Further, the image sensor 1050 may transmit image data in units of at least one frame generated in real time to the control module 1020. The first and second biometric sensors 1031 and 1032 of the surrounding environment detector 1040 may transmit the detected pupil detection signals to the control module 1020.

The control module 1020 may be assembled to at least one side of the support frame 1002 together with the at least one image display module 1010, or may be formed integrally with the support frame 1002. The control module 1020 supplies augmented reality content data to the at least one image display module 1010 so that the at least one image display module 1010 displays an augmented reality content, e.g., an augmented reality content image. At the same time, the control module 1020 may receive sensing signals, image data, and pupil detection signals from the surrounding environment detector 1040 in real time.

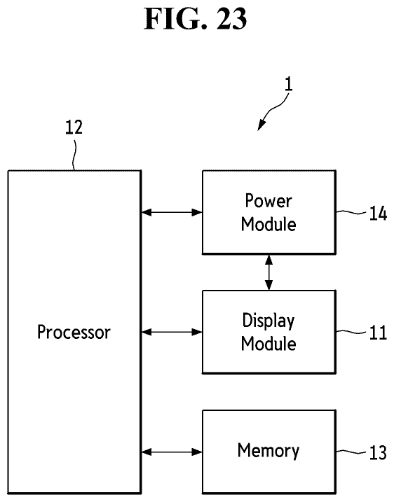

Besides, the display device 10 according to the above-described embodiments may be applied to various electronic devices 1 (see FIG. 23) in addition to the head-mounted display 1000 and the augmented reality content providing device 1000_1 described above. An electronic device 1 (see FIG. 23) according to one or more embodiments may include the above-described display device 10, and may further include, in addition to the display device 10, a module or device having other additional functions.

FIG. 23 is a block diagram of an electronic device according to one or more embodiments.

Referring to FIG. 23, the electronic device 1 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller.

The memory 13 may store data information required for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module, such as a power adapter or a battery device, and a power conversion module that converts power supplied by the power supply module to generate power required for the operation of the electronic device 1.

At least one of the components of the electronic device 1 described above may be included in the display device 10 according to the embodiments described above. Further, some of individual modules functionally included in one module may be included in the display device 10 and some others may be provided separately from the display device 10. For example, the display device 10 may include the display module 11, and the processor 12, the memory 13, and the power module 14 may be provided in the form of other devices in the electronic device 1 other than the display device 10.

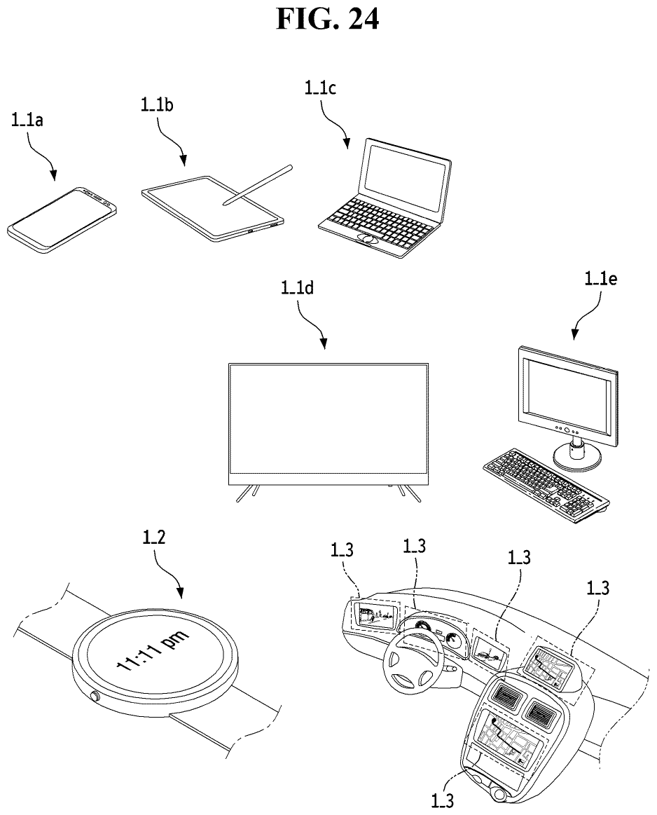

FIG. 24 is schematic views of electronic devices according to various embodiments.

Referring to FIG. 24, various electronic devices 1 to which the display device 10 according to embodiments is applied may include not only an image display electronic device 1, such as a smartphone 1_1a, a tablet PC 1_1b, a laptop 1_1c, a TV 1_1d, and a desk monitor 1_1e, but also a wearable electronic device 1 including a display module, such as a smart watch 1_2, or the like, a vehicle electronic device 1_3 including a display module, such as a center fascia, and a dashboard of an automobile, a center information display (CID) placed on the dashboard, a room mirror display, and the like.

In concluding the detailed description, those skilled in the art will appreciate that many variations and modifications can be made to the embodiments without substantially departing from the aspects of the present disclosure. Therefore, the disclosed embodiments of the present disclosure are used in a generic and descriptive sense only and not for purposes of limitation.

What is claimed is:

1. A display device comprising:
a display panel;
a first polarizing film above the display panel;
a first phase retardation on the first polarizing film; and
a triplet lens above the first polarizing film, and comprising:
a semi-transmissive reflective film;
a first lens above the semi-transmissive reflective film;
a second lens above the first lens;
a second phase retardation film above the second lens;
a second polarizing film above the second phase retardation film;
a third lens above the second polarizing film; and
a first adhesive layer between the first lens and the second lens, and having a refractive index that is greater than a refractive index of the first lens and a refractive index of the second lens.

2. The display device of claim 1, wherein the triplet lens further comprises a second adhesive layer between the second lens and the third lens, and having a refractive index that is greater than the refractive index of the second lens and a refractive index of the third lens.

3. The display device of claim 1, wherein the refractive index of the first adhesive layer is equal to or greater than about 1.7.

4. The display device of claim 1, wherein the refractive index of the first lens and the refractive index of the second lens are less than about 1.7.

5. The display device of claim 1, wherein the triplet lens comprises a first surface facing the display panel, and a second surface opposite the first surface, and
wherein respective average curvatures of the first surface and the second surface are different.

6. The display device of claim 5, wherein the first surface and the second surface are aspherical surfaces.

7. The display device of claim 1, wherein the triplet lens comprises plastic.

8. The display device of claim 7, wherein the first lens comprises at least one of polymethylmethacrylate (PMMA)-based plastic or cyclic olefin copolymer (COC)-based plastic,
wherein the second lens comprises polycarbonate (PC)-based plastic, and
wherein the third lens comprises at least one of polymethylmethacrylate (PMMA)-based plastic or cyclic olefin copolymer (COC)-based plastic.

9. The display device of claim 1, wherein the first lens, the second lens, and the third lens comprise a magnifying lens.

10. An electronic device comprising the display device of claim 1, and further comprising a processor configured to provide a signal to the display device.

11. A display device comprising:
a display panel;
a first polarizing film above the display panel;
a first phase retardation film on the first polarizing film;
a semi-transmissive reflective film above the first phase retardation film;
a first lens above the semi-transmissive reflective film and comprising a doublet lens in which a first sub-lens and a second sub-lens are bonded by an adhesive layer having a refractive index that is greater than a refractive index of the first sub-lens and a refractive index of the second sub-lens;
a second phase retardation film above the first lens;
a second polarizing film above the second phase retardation film; and
a second lens above the second polarizing film.

12. The display device of claim 11, wherein the refractive index of the adhesive layer is equal to or greater than about 1.7.

13. The display device of claim 11, wherein the refractive indices of the first sub-lens and the second sub-lens are less than about 1.7.

14. The display device of claim 11, wherein the first lens comprises plastic.

15. An electronic device comprising the display device of claim 11, and further comprising a processor configured to provide a signal to the display device.

16. A display device comprising:
a display panel;
a first polarizing film above the display panel;
a first phase retardation film on the first polarizing film;
a semi-transmissive reflective film above the first phase retardation film;
a first lens above the semi-transmissive reflective film;
a second phase retardation film above the first lens;
a second polarizing film above the second phase retardation film; and
a second lens above the second polarizing film and comprising a doublet lens in which a first sub-lens and a second sub-lens are bonded by an adhesive layer having a refractive index that is greater than a refractive index of the first sub-lens and a refractive index of the second sub-lens.

17. The display device of claim 16, wherein the refractive index of the adhesive layer is equal to or greater than about 1.7.

18. The display device of claim 16, wherein the refractive index of the first sub-lens and the refractive index of the second sub-lens are less than about 1.7.

19. The display device of claim 16, wherein the second lens comprises plastic.

20. An electronic device comprising the display device of claim 14, and further comprising a processor configured to provide a signal to the display device.
